(19) United States
(12) Patent Application Publication
(10) Pub. No.: US 2011/0235017 A1
(43) Pub. Date: Sep. 29, 2011

(54) PHYSICAL INFORMATION ACQUISITION DEVICE, SOLID-STATE IMAGING DEVICE AND PHYSICAL INFORMATION ACQUISITION METHOD

(75) Inventor: Masanori Iwasaki, Kanagawa (JP)

(73) Assignee: SONY CORPORATION, Tokyo (JP)

(21) Appl. No.: 13/043,871

(22) Filed: Mar. 9, 2011

(30) Foreign Application Priority Data
Mar. 24, 2010 (JP) 2010-067231

(51) Int. Cl. G01C 3/08; G01J 3/46; G01J 5/10; H01L 27/146

(52) U.S. Cl. 356/4.01; 250/226; 250/338.1; 250/208.1; 250/394

(57) ABSTRACT

Disclosed herein is a physical information acquisition device including an electromagnetic wave output section, a first detection section, and a signal processing section. The electromagnetic wave output section is adapted to generate electromagnetic wave at a wavelength equivalent to a specific wavelength when, for a first wavelength range of electromagnetic wave, a wavelength where electromagnetic wave energy is lower than at other wavelengths is determined to be the specific wavelength. The first detection section is adapted to detect electromagnetic wave at the specific wavelength. The signal processing section is adapted to perform signal processing based on detection information acquired from the first detection section.

### BACKGROUND OF THE INVENTION

1. Field of the Invention

The present invention relates to a physical information acquisition device, solid-state imaging device and physical information acquisition method.

2. Description of the Related Art

Arrangements are known such as using a light source (different light source or measurement light source) different from a normal light source such as the outdoor solar light and the indoor illumination light to irradiate an object with light at a predetermined wavelength from the different light source, thus detecting reflected light from the object and processing various signals based on detection information obtained from the detection (refer to Japanese Patent Laid-Open No. Hei 7-218232, Japanese Patent Laid-Open No. Hei 11-153408, Japanese Patent Laid-Open No. 2003-185412, Japanese Patent Laid-Open No. 2009-014459, JP-T-2009-524072, referred to as Patent Documents 1 to 5, respectively, hereinafter).

For example, an active measurement method irradiates an object with near infrared light and receives reflected light with a sensor, thus detecting the distance to the object and acquiring a three-dimensional image.

### SUMMARY OF THE INVENTION

In the existing arrangement, however, light from the normal light source disturbs light from the different light source, making it occasionally impossible to acquire correct information.

Typically, disturbance noise caused by solar light is a serious problem when the arrangement is used outdoors. In an extreme case, solar light is so intense that the photoreception element becomes saturated.

Among possible countermeasures against these problems are increasing the intensity of light from the different light source, canceling out the noise component of solar light by taking the difference and adding a special circuit adapted to prevent saturation. However, all these countermeasures have their drawbacks. For example, it is basically difficult to increase the S/N ratio because of the presence of fundamental disturbance noise caused by the intense solar light. Adding a circuit to prevent saturation leads to a larger circuit scale.

The present invention has been made in light of the foregoing, and it is an aim of the present invention to provide an arrangement for alleviating the impact of disturbance noise caused by a normal light source by using a simpler method when information derived from light emitted from a different light source is acquired.

According to an embodiment of the present invention, there is a physical information acquisition device including an electromagnetic wave output section adapted to generate electromagnetic wave at a wavelength equivalent to a specific wavelength when, for a first wavelength range of electromagnetic wave, a wavelength where electromagnetic wave energy is lower than at other wavelengths is determined to be the specific wavelength, a first detection section adapted to detect electromagnetic wave at the specific wavelength, and a signal processing section adapted to perform signal processing based on detection information acquired from the first detection section. Imaging (acquisition of information derived from a different light source) is conducted by detecting light relating to the specific wavelength. The term “wavelength equivalent to a specific wavelength” refers to a wavelength that is typically the same as the specific wavelength but may be slightly different therefrom.

That is, detection is conducted by matching the wavelength of a measurement light source to that at which electromagnetic wave energy contained in the environment as a light source is low. It should be noted that the term “electromagnetic wave energy contained in the environment as a light source is low” may also be referred to as “spectral characteristic is low” or “spectral distribution is low.” Further, a light source in the environment (e.g., solar light or illumination light) serving as a light source may be referred to as a normal light source.

Then, electromagnetic wave is irradiated onto an object at a wavelength equivalent to the specific wavelength (hereinafter also simply referred to as “at the specific wavelength). The electromagnetic wave at the specific wavelength reflected by the object is detected by a detection section. Signal processing is performed based on detection information acquired from the detection section. Signal processing here is designed to acquire information derived from electromagnetic wave at the specific wavelength.

A typical configuration includes an electromagnetic wave irradiation section adapted to irradiate irradiation light onto an object whose image is to be acquired, a first detection section adapted to detect electric charge of an image component when the object is illuminated with irradiation light irradiated from the electromagnetic wave irradiation section, a second detection section adapted to detect electric charge of the image component when the object is illuminated with natural light, and a signal processing section adapted to perform signal processing based on detection information acquired from the first and second detection sections. The electromagnetic wave irradiation section generates light at some specific wavelengths in the wavelength range other than the range of visible wavelengths. Here, the electromagnetic wave irradiation section generates light at some specific wavelengths in the wavelength range other than the range of visible wavelengths.

Detection of reflected light after irradiating an object with electromagnetic wave at the specific wavelength where electromagnetic wave energy is lower than at other wavelengths allows for detection of at least the specific wavelength component without this component being buried in a normal light source component in a first wavelength range. Therefore, it is possible to acquire information derived from electromagnetic wave at the specific wavelength that is less affected by disturbance noise caused by the normal light source by comparing detection information acquired when electromagnetic wave at the specific wavelength is irradiated onto an object with detection information acquired when no electromagnetic wave at the specific wavelength is irradiated onto the object.

However, this alone leads to detection of not only the specific wavelength component but also the normal light source component at the same time, possibly resulting in saturation of the detection section if the light intensity of the normal light source is high.

As a countermeasure, an optical member is preferably provided in the imaging optical path that has a narrow band-pass characteristic centered around the specific wavelength. This allows for detection of only the specific wavelength component, thus keeping the detection section unaffected even in the event of a high light intensity of the normal light source.

That is, according to an embodiment of the present invention, there is a solid-state imaging device including a detection section adapted to detect a component emitted from an electromagnetic wave output section adapted to generate electromagnetic wave at a wavelength equivalent to a specific wavelength when, for a first wavelength range of electromagnetic wave, a wavelength where electromagnetic wave energy is lower than at other wavelengths is determined to be the specific wavelength, the component reflected by an object. An optical member having a band-pass characteristic centered around the specific wavelength is provided in the imaging optical path. Further, there is a physical information acquisition method comprising the steps of irradiating an object with electromagnetic wave at a wavelength equivalent to a specific wavelength when, for a first wavelength range of electromagnetic wave, a wavelength where electromagnetic wave energy is lower than at other wavelengths is determined to be the specific wavelength, detecting electromagnetic wave at the specific wavelength reflected by the object with a detection section, and performing signal processing based on detection information acquired from the detection section. Detection of reflected light after irradiating the object with the specific wavelength wave allows for detection of the specific wavelength component without this component being buried in a normal light source component. It is possible to acquire information derived from the specific wavelength wave that is less affected by disturbance noise caused by the normal light source by comparing detection information acquired when the specific wavelength wave is irradiated onto the object with detection information acquired when no specific wavelength wave is irradiated onto the object. If an optical member having a band-pass characteristic is additionally used in combination, only the specific wavelength component can be detected, thus keeping the detection section unaffected and free from saturation even in the event of a high light intensity of the normal light source.

A mode of the present invention allows for acquisition of information derived from electromagnetic wave at the specific wavelength that is less affected by disturbance noise caused by a normal light source simply by irradiating an object with electromagnetic wave at the specific wavelength where electromagnetic wave energy is lower than at other wavelengths.

### BRIEF DESCRIPTION OF THE DRAWINGS

FIG. 1 is a diagram illustrating an example of arrangement of color separation filters for pixels used to capture a color image in a present embodiment;

FIG. 2 is a diagram illustrating the fundamental optical transmission characteristics (spectral characteristics) of different color filters making up a color filter group;

FIG. 3 is a diagram illustrating examples of characteristics of the different color filters making up the color filter group;

FIG. 4 is a diagram illustrating a rough configuration of an imaging device which is an example of a physical information acquisition device;

FIG. 5 is a diagram describing an image signal processing section;

FIGS. 6A to 6D are diagrams illustrating a first example of a second embodiment;

FIGS. 7A to 7D are diagrams illustrating a second example of the second embodiment;

FIGS. 8A and 8B are diagrams illustrating modification examples of the second example of the second embodiment;

FIGS. 9A and 9B are diagrams illustrating a third example of the second embodiment;

FIGS. 10A and 10B are diagrams illustrating a fourth example of the second embodiment;

FIGS. 11A and 11B are diagrams illustrating a fifth example of the second embodiment;

FIGS. 12A and 12B are diagrams illustrating a sixth example of the second embodiment;

FIGS. 13A and 13B are diagrams illustrating a seventh example of the second embodiment;

FIGS. 14A and 14B are diagrams illustrating an eighth example of the second embodiment;

FIGS. 15A to 16C are diagrams illustrating the basic philosophy behind the manufacturing method of an optical member having a narrow band-pass characteristic centered around a specific wavelength;

FIG. 17 is a diagram describing a specific example of the optical member having a band-pass characteristic;

FIGS. 18A and 18B are diagrams describing wavelength components of solar light reaching the ground; and

FIG. 19 is a diagram illustrating a characteristic examples of infrared cutoff filters.

### DETAILED DESCRIPTION OF THE PREFERRED EMBODIMENTS

A detailed description will be given below of the preferred embodiments of the present invention with reference to the accompanying drawings.

It should be noted that the description will be given in the following order:

1. Basic concept (fundamentals of the present embodiments, color separation filters, spectral characteristic of the filters)
2. Imaging device
3. First embodiment (acquisition of high-sensitivity image, acquisition of infrared image, distance measurement)
4. Second embodiment

First example: Transmission of only a given specific wavelength component in the infrared range

Second example: Transmission of only a given specific wavelength component in the infrared range and visible light

Third example: Transmission of only absorbed solar wavelength components in the infrared range (infrared band-pass filters)

Fourth example: Transmission of only absorbed solar wavelength components in the infrared range and visible light

(Visible and Infrared Band-Pass Filters)

Fifth example: “Second or fourth example” and color imaging (with on-chip infrared filter)

Sixth example: “Second or fourth example” and color imaging (without on-chip infrared filter)

Seventh example: Infrared cutoff filters for the visible pixels, on-chip filters for the infrared light pixel

Eighth example: Infrared cutoff filters for the visible pixels, infrared band-pass filters for the infrared light pixel

5. Details of the special optical band-pass filter
6. Comparison with comparative examples

### <Basic Concept>

### Fundamentals of the Present Embodiments

Under an imaging environment, the spectral wavelength characteristic of a light source (normal light source) may not be uniform, with some wavelengths (low energy wavelengths) being relatively lower in energy level than other wavelengths. If imaging is performed with the wavelength of a different light source matched to that of one of the low energy wavelengths, it is possible to alleviate the impact of the noise component derived from the normal light source on the information derived from the different light source.

The arrangement according to the present embodiment has been made with focus on this feature, using a low energy wavelength as a specific wavelength and irradiating a subject with light at a wavelength equivalent to (typically at the same wavelength as) the specific wavelength. Then, light relating to the specific wavelength is detected for imaging (acquisition of information derived from the different light source).

More preferably, an optical member is provided in the imaging optical path that has a band-pass characteristic centered around the specific wavelength to transmit only the wavelength components in the specific wavelength band of the different light source (and visible band). This avoids detection of the components other than the specific wavelength by the detection section, further alleviating the impact of noise caused by the components other than the specific wavelength and avoiding possible saturation.

An image captured with only the normal light source and without the subject being irradiated with the specific wavelength from the different light source is referred to as a normal image. On the other hand, an image captured with the subject being irradiated with the specific wavelength from the different light source is referred to as a measurement image.

In order to facilitate the understanding of the arrangement according to the present embodiment, a description will be given below of a case in which an image is obtained by means of reflected light by using at least infrared light as a different light source. An image (whether monochrome or color) should preferably be obtained by means of natural light in addition to an image obtained by means of reflected light.

### [Color Separation Filters]

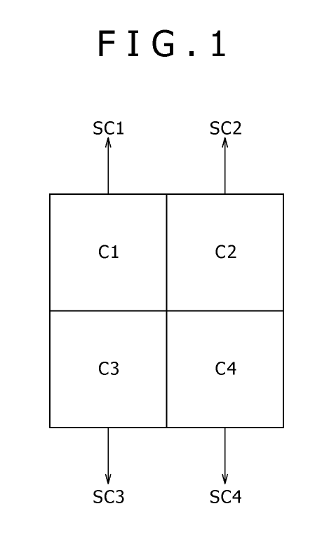

FIG. 1 is a diagram illustrating an example of arrangement of color separation filters for pixels (color arrangement) used to capture a color image in the present embodiment. Here, FIG. 1 is a diagram illustrating a basic structure for an example of color arrangement of color separation filters.

The color separation filters are arranged basically to allow for acquisition of an infrared image (by means of reflected light) and a visible color image independently of each other at all times. As illustrated in FIG. 1, for example, four different types of color filters having different characteristics are arranged in a regular manner (in the form of a square grid in the present example). A color filter C1 is designed for the components in the first wavelength range. Color filters C2, C3 and C4 (each of which transmits the components, i.e., a selective specific wavelength range, in the second wavelength range) are designed for the components of three different wavelength ranges (color components) in the second wavelength range that does not include the first wavelength range.

In the present example, the components in the second wavelength range are visible components. The color filters C1, C2, C3 and C4 are collectively referred to as color filters 14, and detection sections for the color filters 14 are referred to as pixels 12. A red pixel 12R, green pixel 12G and blue pixel 12B are collectively referred to as visible light detection pixels 12VL. The visible light detection pixels 12VL are examples of signal acquisition elements for a specific wavelength range adapted to obtain visible signals such as RGB signals through wavelength separation. If the components in the first wavelength range are infrared light, the pixel 12 for the color filter C1 is referred to as an infrared light pixel 12IR.

Wavelength components are detected by the associated detection sections, made up, for example, of photodiodes via the color filters C1 to C4, thus allowing for detection of the respective components independently of each other. The detection section having the color filter C1 is a first detection section. The detection section having the color filters C2 to C4 is a second detection section. The second detection section having the color filters C2 to C4 is designed to detect the different wavelengths in such a manner as to further separate the second wavelength range (visible range) into different colors.

The color filters C2 to C4 are ideally primary color filters each of which has a transmissivity of about “1” to the color components in the visible range and about “0” to other color components. Alternatively, the color filters C2 to C4 are complementary color filters each of which has a transmissivity of about “0” to the color components in the visible range and about “1” to other color components.

Complementary color filters have higher sensitivity than primary color filters. Therefore, it is possible to enhance the sensitivity of an imaging device by using complementary color filters each of whose transmitted light is a complementary color of one of the three primary colors. Conversely, using primary color filters provides primary color signals without taking the difference, thus making the signal processing of visible color images simpler.

The term transmissivity of about “1” refers to an ideal condition. However, practical filters are inevitably subtractive color filters whose light transmissivity undergoes a relative decline. Even in this case, the filters need only have a transmissivity of the wavelength range of interest that is significantly higher than that for other wavelength ranges. The transmissivity may be partially not “1.” The term, transmissivity of about “0,” on the other hand, similarly refers to an ideal condition. The filters need only have a transmissivity of the wavelength range of interest that is significantly lower than that for other wavelength ranges. The transmissivity may be partially not “0.”

Further, whether the filters are primary or complementary color filters, the filters need only pass the components in the wavelength range for a predetermined color (primary or complementary color) in the visible range. Therefore, whether they pass wavelengths in the ultraviolet or infrared range, that is, their transmissivity of ultraviolet or infrared light, does not matter. Naturally, the transmissivity of about “0” to ultraviolet and infrared light is advantageous in terms of color reproducibility.

For example, various color filters commonly used today offer a high transmissivity of red, green or blue but a low transmissivity of other colors (e.g., green and blue if the color of interest is red) in the visible band. However, there are no specifications as to their transmissivity of the wavelengths outside the visible band. Generally, these filters have a high transmissivity of the color of interest than that of other colors (e.g., green and blue if the color of interest is red), with, for example, sensitivity to the infrared range and light transmissivity in the infrared range. However, the first embodiment basically remains unaffected even in the event of a high transmissivity of the wavelengths outside the visible band although there is a problem of color reproducibility. Naturally, it is preferred that an arrangement be provided to eliminate the infrared components for the second wavelength range.

On the other hand, the color filter C1 need only have a characteristic that allows for the pixel 12 having the color filter C1 to serve as a pixel (typically infrared light pixel 12IR) adapted to detect the longer wavelength components (typically, infrared light component) outside the visible band (invisible components). That is, the color filter C1 need only transmit the longer wavelength components in the first wavelength range (infrared light in the present example).

As a first approach, the color filter C1 may be a so-called visible cutoff filter that blocks the components in the second wavelength range (i.e., visible components) passing through the color filters C2 to C4 and passes only the components in the first wavelength range (infrared light in the present example). As a second approach, the color filter C1 may pass the components in all ranges from the second wavelength range (visible light in the present example) to the first wavelength range (infrared light in the present example).

If the second approach is adopted, the color filter C1 need only be designed for a predetermined wavelength range so that the first detection section has higher light utilization efficiency than the second detection section having the color filters C2 to C4. Typically, the color filter C1 should pass the components in all ranges from the second wavelength range (visible light in the present example) to the infrared range. In the first embodiment, the color filter C1 configured as described above is referred to as an all-pass filter.

For example, an all-pass white filter should be used as the color filter C1 so that the first detection section is sensitive to not only blue to red in the visible band but also infrared light. If the second approach is used, a configuration may be adopted in which virtually no color filter is provided as the color filter C1 to be in line with the fact that all wavelength components from visible to infrared light (particularly near infrared light) are passed. In the present embodiment, the term “detected by the first detection section via the color filter C1” applies not only to detection using the color filter C1 but also detection virtually without using any color filter.

The second detection section (e.g., photodiode) of the pixel having the color filters C2 to C4 need only be at least sensitive to visible light and need not be sensitive to near infrared light. If anything, the second detection section should preferably be as insensitive to the components other than visible light components as possible in terms of color reproducibility.

In the first embodiment, the first detection section made up, for example, of a photodiode and having the color filter C1 need be sensitive at least to infrared light (including near infrared light). In a second embodiment, on the other hand, there is no need for the first detection section to be sensitive to the components in the entire infrared range. Instead, the first detection section need only be sensitive at least to a specific wavelength in the infrared range. A detailed description will be given later of the term “specific wavelength.” It should be noted that, as a precondition, the first detection section need detect infrared light which is an example of components in the invisible range. Therefore, infrared light need fall on the first detection section. As a result, an existing popular infrared cutoff filter is removed for imaging.

If the color filter C1 is a visible cutoff filter that passes only infrared light, the first detection section need not be sensitive to visible light. However, if the color filter C1 is an all-pass filter, the first detection section need be also sensitive to visible light.

The first detection section having the color filter C1 is used not only to reproduce physical information (infrared image and wide wavelength range image in the present example) relating to the components in the first wavelength range obtained from the first detection section having the color filter C1 but also as a color or sensitivity correction pixel for the color signal used to reproduce a visible color image obtained from the second detection section having the color filters C2 to C4. The color filter C1 serves as a correction filter for the color filters C2 to C4.

In order to reproduce a visible color image, for example, signal components SC2 to SC4 in the second wavelength range are first detected by the second detection section having the color filters C2 to C4 virtually separately from the components in the first wavelength range (infrared range) that are different from the components in the second wavelength range. Further, a signal component SC1 in a predetermined wavelength range (infrared range or all ranges) including at least the components in the first wavelength range (infrared range) is detected by the first detection section, i.e., another detection section.

Still further, more preferably, correction calculation (particularly calculation for correction of color reproduction) is performed on the signal components SC2 to SC4 using the signal component SC1 to provide excellent color reproduction. Alternatively, correction calculation (particularly correction calculation for higher sensitivity) is performed to provide signals with higher sensitivity.

Various types of information can be obtained depending on whether to pass only the infrared components or both the infrared and visible components through the color filter C1. In addition, correction calculation ensures reduction in undesired components.

In performing various types of correction calculation, it is desirable to compute the matrix of signal outputs obtained from the four wavelength ranges (pixels each having one of the four filters) as an example so as to find a visible color image and near infrared image independently of each other. If four color filters having different filtering characteristics are disposed one on each of the pixels, each made up of an imaging element such as photodiode, and the matrix of outputs from the pixels having the four color filters is calculated, it is possible to simultaneously obtain three primary color outputs for forming a visible color image without being almost completely affected by near infrared light and an output for forming a near infrared image without being almost completely affected by visible light independently of each other.

As for a visible color image in particular, correcting poor color reproduction caused by leakage of infrared light through calculation ensures imaging with high sensitivity at dark locations and excellent color reproduction. A high level of red signal component near infrared light and high luminance in the red areas of the image can also be alleviated, thus adjusting a balance between improved color reproducibility and enhanced sensitivity under a low illumination condition at low cost without using any special imaging element or mechanism.

As for specific approaches for calculation for color correction and correction calculation for higher sensitivity, the description will be omitted in the present specification. However, reference should be made, for example, to Japanese Patent Laid-Open Nos. 2007-329380 and 2007-288549.

In FIG. 1, a case is shown in which a pattern of color separation filters is repeated in units of two-by-two pixels. However, this is merely an example. Practically, the pattern of color separation filters to be repeated and the arrangement of the filters C1 to C4 need only be determined, for example, according to which of the two options, the resolution of a visible image and that of an infrared image, is given priority.

In this case, a pixel for the wide wavelength range (wide wavelength range pixel 12A) is, for example, added to visible pixels with existing red, green and blue primary color filters or cyan, magenta and yellow complementary color filters (or green primary color filter). In reality, however, one of the visible pixels is replaced by the wide wavelength range pixel 12A based on the existing filter arrangement. At this time, the reduction in resolution of the visible image or a wide wavelength range image (i.e., luminance image) obtained by the wide wavelength range pixel 12A can be suppressed by devising a proper arrangement of the pixel (e.g., green pixel 12G) whose wavelength component contributes significantly to the resolution of the wide wavelength range pixel 12A and visible image.

In FIG. 1, not only an image of the components in the first wavelength range via the color filter C1 but also three different images of the components in the second wavelength range via the color filters C2 to C4 can be obtained. However, this is not absolutely essential. For example, if filters of the same color are used for the color filters C2 to C4, single color images can be obtained. Further, using filters of the same color as the color filter C1 for the color filters C2 to C4 provides images of only the components in the first wavelength range.

### [Spectral Characteristic of the Filters]

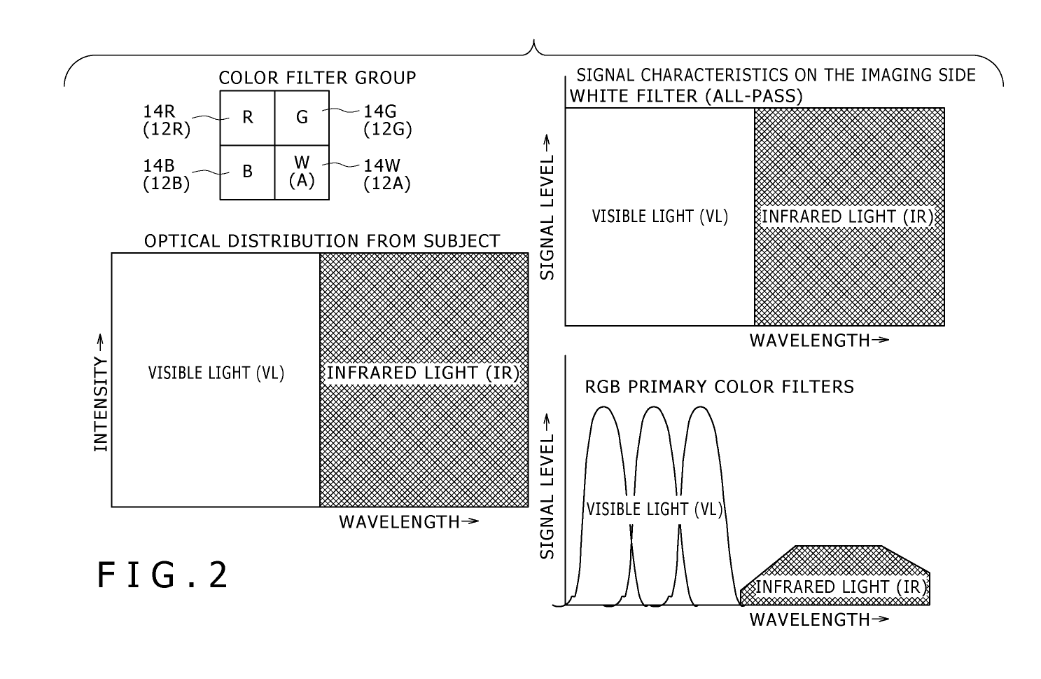

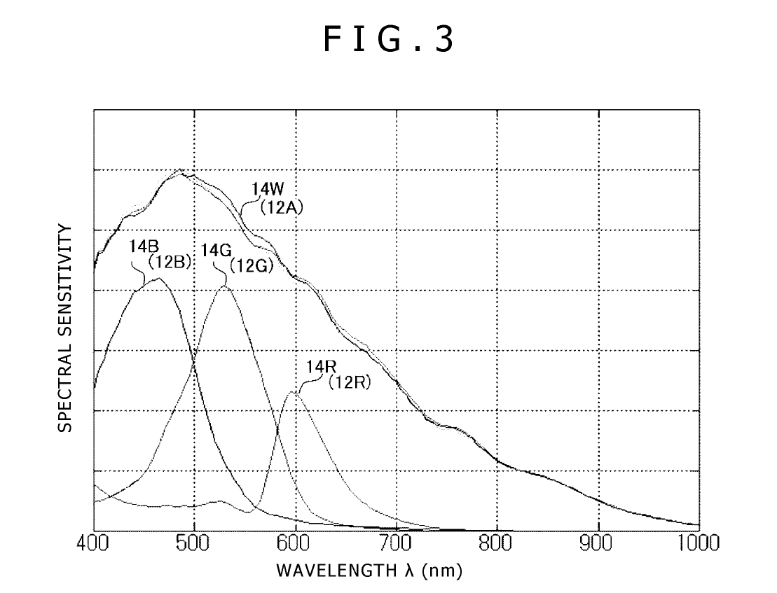

FIGS. 2 and 3 are diagrams describing specific examples of wavelength separation. Here, FIG. 2 is a diagram illustrating the fundamental optical transmission characteristics (spectral characteristics) of different color filters making up a color filter group, and FIG. 3 is a diagram illustrating examples of characteristics of the different color filters making up the color filter group.

First, in the present example, a case is shown in which a color filter group is made up of four color filters R, G, B and W (A) having different spectral characteristics as color filters 14, i.e., red (R) that passes the wavelengths around red, green (G) that passes the wavelengths around green, blue (B) that passes the wavelengths around blue and white (W) (or no color filter (A)) that passes infrared light (IR) and all of red, green and blue.

The spectra of the color filters 14 include channels R, G and B and a channel A (=Y+IR) adapted to pass infrared light (IR) and all of red, green and blue. The pixels associated therewith, i.e., the red, green and blue pixels 12R, 12G and 12B and wide wavelength range pixel 12A adapted to detect infrared light (IR) and all of red, green and blue, provide a mosaic image made up of four different spectra.

Providing the wide wavelength range pixel 12A allows for measurement of a wide wavelength range signal SA which represents a composite component of the infrared light IR and visible light incident upon the imaging element, i.e., which contains both the luminance signal (Y) of the visible area and the infrared signal (IR).

It should be noted that, in FIG. 2, the white filter 14W is shown to have the same transmission characteristic for the visible and infrared bands. However, this is not absolutely essential. The transmitted intensity of the infrared band may be lower than that of the visible band. The white filter 14W need only be capable of transmitting all the wavelength components in the visible band with sufficient intensity and transmitting the wavelength components in the infrared band with sufficiently higher intensity than the red, green and blue primary color filters.

However, the wide wavelength range signal SA obtained from the wide wavelength range pixel 12A contains not only the infrared component IR but also a visible component VL. Using the wide wavelength range signal SA as it is allows for the infrared component IR to be used as a luminance component, thus providing higher sensitivity than generating a luminance signal with only the visible component VL. This is advantageous in that a luminance signal with minimal noise can be obtained particularly during imaging under a low illumination condition.

More particularly, filters for primary colors of the visible light VL (wavelength λ from 380 to 780 nm), i.e., one centered around the blue component B (e.g., transmissivity of about “1” for wavelength λ from 400 to 500 nm and about “0” for other wavelengths), another centered around the green component G (e.g., transmissivity of about “1” for wavelength λ from 500 to 600 nm and about “0” for other wavelengths), and still another centered around the red component R (e.g., transmissivity of about “1” for wavelength λ from 600 to 700 nm and about “0” for other wavelengths), are used as the color filters 14 for capturing a visible color image.

The term, transmissivity of about “1,” refers to an ideal condition. The filters need only have a transmissivity of the wavelength range of interest that is significantly higher than that for other wavelength ranges. The transmissivity may be partially not “1.” The term, transmissivity of about “0,” on the other hand, similarly refers to an ideal condition. The filters need only have a transmissivity of the wavelength range of interest that is significantly lower than that for other wavelength ranges. The transmissivity may not be partially “0.”

The filters need only pass the components in the wavelength range for a predetermined color (primary or complementary color) in the range of the visible light VL, i.e., the components passing in the wavelength range. Therefore, whether they pass wavelengths in the range of the infrared light IR, i.e., the components in the range of reflected wavelengths, that is, their transmissivity of the infrared light IR, does not matter.

As an example, the filters having spectral sensitivity characteristics as shown in FIG. 3 can be used. For instance, the blue filter 14B for channel B has a high transmissivity of optical signals of 380 nm to 480 nm in wavelength equivalent to blue. The green filter 14G for channel G has a high transmissivity of optical signals of 450 nm to 550 nm in wavelength equivalent to green. The red filter 14G for channel R has a high transmissivity of optical signals of 550 nm to 650 nm in wavelength equivalent to red. It should be noted that these color filters 14R, 14G and 14B for red, green and blue transmit almost no infrared components of about 700 nm or more in wavelength.

On the other hand, the white filter 14W for channel A has a peak transmissivity at about 500 nm. However, this filter transmits not only all red, green and blue component signals but also infrared components beyond 700 nm. The wide wavelength range pixel 12A for the white filter 14W can detect both visible and infrared components. This allows for the wide wavelength range pixel 12A to offer higher detection sensitivity than other pixels (red, green and blue pixels 12R, 12G and 12B in the present example) each adapted to detect the components in one of a plurality of ranges into which the visible range is divided.

It should be noted that, in the present example, the white filter 14W has more or less the same transmissivity of the visible range as the ratio of transmissivity of the different visible ranges between the blue, green and red filters 14B, 14G and 14R. This provides the white filter 14W with a higher transmissivity as a whole and the wide wavelength range pixel 12A with higher sensitivity to the visible range than the red, green and blue pixels 12R, 12G and 12B while at the same time taking into consideration white balance for the wide wavelength range pixel 12A in the visible range. The fact that the detection of infrared components, i.e., an example of invisible components, is possible provides the wide wavelength range pixel 12A with higher sensitivity. In addition, the wide wavelength range pixel 12A offers higher detection sensitivity to the visible range than other pixels (red, green and blue pixels 12R, 12G and 12B in the present example) each adapted to detect the components in one of a plurality of ranges into which the visible range is divided, thus providing even higher sensitivity.

Although not described in detail, the correction of the color signals obtained respectively from the red, green and blue pixels 12R, 12G and 12B using high-sensitivity red, green and blue components in the visible range from the wide wavelength range pixel 12A provides color signals with even higher sensitivity.

Here, in the case of common imaging elements, due consideration has been given to the sensitivity of their detection section such as so-called photodiode made up of a semiconductor layer to the visible components. Therefore, these imaging elements offer adequate sensitivity to the visible components but not to the infrared components.

For example, it is clear from FIG. 3 that the wide wavelength range pixel 12A having the all-pass white filter 14W for channel A has sufficient sensitivity in the visible range and that the spectral sensitivity curve thereof shows a higher spectral sensitivity than those of the red, green and blue pixels. On the other hand, it is also clear that the same pixel 12A shows a significant decline in sensitivity at longer wavelengths, and particularly in the infrared range. For example, it is clear that the sensitivity of the wide wavelength range pixel 12A peaks at a wavelength of about 500 nm, that the sensitivity declines at longer wavelengths, and that the sensitivity declines to less than half of the peak level in the infrared range beyond 700 nm. This means that although possibly having an optimal device structure for the visible band, the solid-state imaging element does not have an optimal device structure to provide proper sensitivity up to longer wavelengths of infrared light, and that the device structure thereof is not optimal for longer wavelengths.

In order to resolve this problem, therefore, the following idea is applied to the side of the device so as to provide sufficient sensitivity even in the range of longer wavelengths. More specifically, the effective area of the detection section such as photodiode for longer wavelengths (thickness of the detection section from the surface) is expanded deeper into the semiconductor layer so as to provide sufficient sensitivity in the range of longer wavelengths for improved sensitivity.

It should be noted, however, that if the effective area is simply thickened, it takes long time for signal charge (carriers such as electrons) generated at deep locations of the photodiode to migrate to the surface, making it problematic to read the signal. Modulation doping is preferred as a countermeasure against this problem (refer, for example, to Japanese Patent No. 4396684). For example, if an n-type substrate is used, modulation doping is performed so that the deeper the location from the semiconductor surface, the lower the doping concentration of arsenic As, an example of n-type (first conductivity type) dopant.

### <Imaging Device>

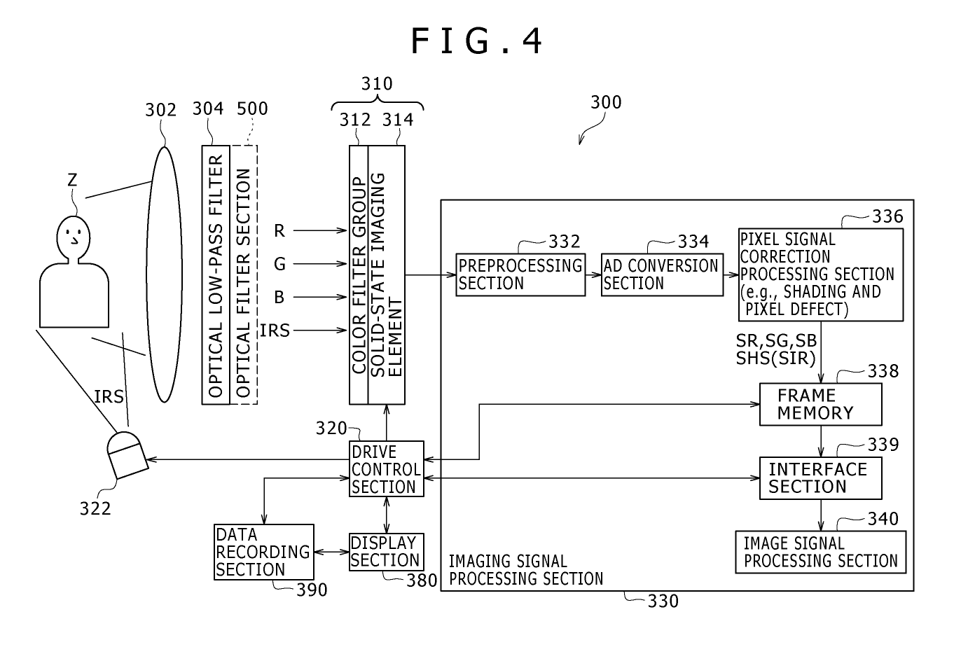

FIG. 4 is a diagram illustrating a rough configuration of an imaging device which is an example of a physical information acquisition device. This imaging device 300 obtains a visible color image and infrared image independently of each other.

The imaging device 300 includes an imaging optical system 302, optical low-pass filter 304, imaging section 310 (solid-state imaging device), drive control section 320, light-emitting section 322, imaging signal processing section 330, display section 380 and data recording section 390.

The imaging optical system 302 includes an imaging lens as a main component and guides light L carrying the image of a subject Z onto the imaging section, thus forming an image. The imaging section 310 includes a color filter group 312 and solid-state imaging element 314 (image sensor). The drive control section 320 drives the solid-state imaging element 314.

The light-emitting section 322 is an example of electromagnetic wave irradiation section or electromagnetic wave output section and irradiates the subject with measurement light. The same section 322 is characterized in the wavelength band of emitted light. The wavelength of light emitted by the same section 322 is matched to a low spectral characteristic wavelength or low spectral distribution wavelength, i.e., low energy wavelength (=specific wavelength) that is relatively lower in electromagnetic wave energy level than other wavelengths in the wavelength band of disturbance light. The term “matched” refers to the fact that the wavelength of emitted light is equivalent to the specific wavelength. The two wavelengths should preferably be the same but may be slightly different therefrom. However, the more different the two wavelengths are, the more affected the emitted light is by undesired components.

For example, it is known that specific solar wavelengths reaching the ground are absorbed by the atmosphere. Therefore, the present embodiment focuses on the characteristics of solar wavelengths reaching the ground, making use of the absorbed wavelength band with an extremely small light intensity as light emitted from the light source as a specific light source. In the camera system implementing this approach, the light-emitting section 322 uses a light source containing a specific wavelength (absorbed wavelength band) component IRS in the infrared band to irradiate the subject Z.

The imaging signal processing section 330 processes various imaging signals SIR (infrared component) and SV (visible component) output from the solid-state imaging element 314.

The optical low-pass filter 304 blocks high frequency components beyond the Nyquist frequency to prevent aliasing distortion. Further, as illustrated by a dotted line in FIG. 4, an optical filter section 500 may be provided in combination with the same filter 304 to suppress undesired components (e.g., infrared components for longer wavelengths and ultraviolet light components for shorter wavelengths) other than visible components. For example, an infrared cutoff filter is typically provided as the optical filter section 500. In this regard, the present imaging device is identical to common imaging devices.

The optical filter section 500 and color filter group 312 are examples of an optical member having a light filtering characteristic in an imaging optical system. In the first embodiment, an infrared cutoff filter is basically not provided in view of the combination with signal processing which will be described later. In the second embodiment which will be described later, a special (having a narrow band-pass characteristic) optical member (optical band-pass filter) is used that treats, for example, the absorbed solar wavelengths as specific wavelengths and removes roughly all wavelengths other than the specific wavelength components, unlike a common infrared cutoff filter adapted to suppress the majority of components in the infrared range.

If a visible color image and near infrared image are obtained independently of each other, an optical member (referred to as a wavelength separation optical system) may be provided to separate light L1 incident via the imaging optical system 302 into the infrared light IR, an example of invisible light, and visible light VL. In the present configuration, however, no wavelength separation optical system adapted to separate light into different wavelengths is not provided in the incident optical system.

The solid-state imaging element 314 includes a group of photoelectric conversion pixels formed in a two-dimensional matrix. It should be noted that, as for the specific configuration of the solid-state imaging element 314 used in the present embodiment, at least the semiconductor layer to which the sensitivity enhancement approach has been applied for the long wavelength range is used. The detection section such as photodiode is formed in the semiconductor layer. On the other hand, there are no particular limitations to the arrangement adapted to separate light into the visible range, an example of the first wavelength range, and the infrared range, an example of the second wavelength range.

On the imaging surface of the solid-state imaging element 314, electric charge is generated which is commensurate with the infrared light IR and visible light VL carrying the image of the subject Z. The operation adapted to store electric charge and adapted to read electric charge are controlled by means of a sensor drive pulse signal output to the drive control section 320 from a system control circuit not shown.

The electric charge signals read from the solid-state imaging element 314, i.e., the infrared imaging signal SIR carrying an infrared image and a visible imaging signal SVL carrying a visible image, are transmitted to the imaging signal processing section 330 for predetermined signal processing.

For example, the imaging signal processing section 330 includes a preprocessing section 332, AD (analog-to-digital) conversion section 334, pixel signal correction processing section 336, frame memory 338, interface section 339 and image signal processing section 340.

In FIG. 4, a reflected light image acquisition section includes the light-emitting section 322 and a natural light image acquisition section. That is, the reflected light image acquisition section and natural light image acquisition section share whatever can be shared. The two sections differ in the presence or absence of the light-emitting section 322 and share all components other than the same section 322. The natural light image acquisition section includes the functional sections from the imaging optical system 302 to immediately before the image signal processing section 340 (in other words, the sections other than the light-emitting section 322 and image signal processing section 340). Naturally, this is merely an example, and the reflected light image acquisition section and natural light image acquisition section may be two separate image acquisition sections, for example.

The light-emitting section 322 irradiates the subject Z with irradiation light according to control information supplied from the drive control section 320. The image of the subject Z is formed on the solid-state imaging element 314 by the imaging optical system 302. The solid-state imaging element 314 includes two charge accumulation sections, the first charge accumulation section adapted to accumulate electric charge used for imaging (visible band detection section for C2 to C4) and the second charge accumulation section (infrared band detection section for C1).

The preprocessing section 332 performs preprocessing including black level adjustment, gain adjustment and gamma correction on the sensor output signal (visible imaging signal SVL and infrared imaging signal SIR) from the solid-state imaging element 314.

The AD conversion section 334 converts the analog signal output from the preprocessing section 332 into a digital signal.

The pixel signal correction processing section 336 corrects shading caused by the imaging optical system 302 and pixel defect in the solid-state imaging element 314.

The video signal output from the solid-state imaging element 314 is amplified by the preprocessing section 332 first, followed by conversion into digital data by the AD conversion section 334, correction of shading and other problems by the pixel signal correction processing section 336 and storage in the frame memory 338. The digital image data stored in the frame memory 338 is output via the interface section 339 in response to a request from the image signal processing section 340.

The image signal processing section 340 performs predetermined signal processing based on imaging information of the subject Z with a different color and sensitivity level for each pixel according to the arrangement pattern of the color filters C1 to C4 (mosaic pattern). Among examples of types of signal processing performed are sensitivity enhancement of normal and infrared images, measurement of the distance to the subject based on image information derived from the components of light at the specific wavelength emitted from the light-emitting section 322 and object detection.

For example, the time of flight of light is measured using the time of flight (TOF) method by irradiating the subject Z and receiving reflected light, thus measuring the distance to the subject Z based on the time of flight of light or acquiring a three-dimensional image of the subject Z.

The display section 380 has, for example, a liquid crystal display (LCD) or organic EL display and displays an image commensurate with the video signal fed from the drive control section 320.

The data recording section 390 has a codec (acronym for coder/decoder or compression/decompression) to not only record image information, supplied from the drive control section 320 and display section 380, to its memory (recording medium) such as flash memory adapted to store image signals but also read stored information, decode the information and supply the decoded information to the drive control section 320 and display section 380.

### First Embodiment

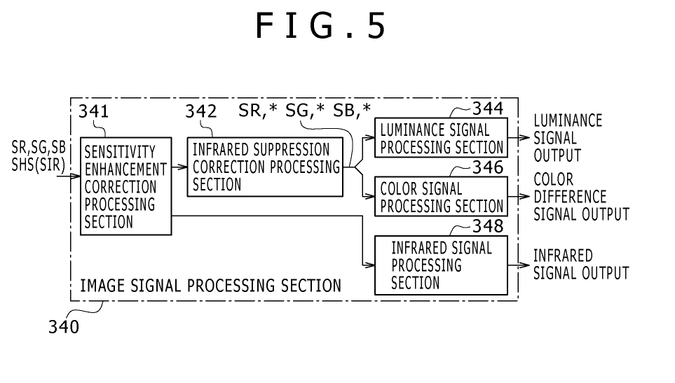

FIG. 5 is a diagram describing an image signal processing section 340. The image signal processing section 340 includes a sensitivity enhancement correction processing section 341. The same section 341 images the subject Z with a different color and sensitivity level for each pixel according to the arrangement pattern of the color filters C1 to C4 (mosaic pattern) and converts a color/sensitivity mosaic image having colors and sensitivity levels in a mosaic pattern into an image in which each pixel has all color components and a uniform sensitivity level.

The sensitivity enhancement correction processing section 341 obtains a signal representing the amount of photometry (measured amount) based on unit signals, one for each wavelength, detected by the second detection section adapted to detect signals via the color filters C2 to C4. The same section 341 uses this signal representing the amount of photometry and the high-sensitivity signals of the respective color components in the second wavelength range detected by the first detection section adapted to detect signals via the color filter C1 to perform calculation so as to correct the sensitivity of the unit signal (color signal) of each wavelength detected by the second detection section. More specifically, calculation for sensitivity correction is achieved by multiplying the color signal of each wavelength detected by the second detection section by the ratio between the signal representing the amount of photometry and high-sensitivity color signal detected by the first detection section.

Therefore, the sensitivity enhancement correction processing section 341 includes a luminance image generation/processing section and single color image processing section although these sections are not illustrated. The luminance image generation/processing section generates a luminance image as a signal representing the amount of photometry from a color/sensitivity mosaic image obtained from the imaging operation. The single color image processing section generates single color images R, G and B using the color/sensitivity mosaic image and luminance image. It should be noted that a process adapted to generate a luminance image or single color image serving as information having uniform color and sensitivity level at all pixel positions from a mosaic image serving as imaging information in a mosaic pattern having different wavelength components (color components) and sensitivity levels is referred to as demosaicing process.

The sensitivity enhancement correction processing section 341 also includes a sensitivity enhancement correction section. The sensitivity enhancement correction section generates the single color images R, G and B corrected to provide higher sensitivity by correcting the single color images, obtained from the single color image processing section, using the luminance image (representing the amount of photometry) obtained from the luminance image generation/processing section and a high-sensitivity imaging signal SHS obtained via the color filter C1.

A single color image processing section generates a single color image by interpolating the color/sensitivity mosaic images using nearby pixel signals SR, SG and SB of the same colors based on each of the color/sensitivity mosaic images obtained via the red, green and blue filters and color mosaic pattern information and sensitivity mosaic pattern information representing the arrangement pattern of the red, green and blue filters. All the obtained pixels of the single color image generated by the single color image processing section have a pixel value of each color component.

Similarly, a luminance image generation processing section generates a wide wavelength range image by interpolating the color/sensitivity mosaic image using a nearby pixel signal SA of the same color based on the color/sensitivity mosaic image obtained via the color filter C1, color mosaic pattern information and sensitivity mosaic pattern information representing the arrangement pattern of the color filter C1. All the obtained pixels of the wide wavelength range image generated by the luminance image generation processing section have a pixel value of wide wavelength range signal component. The luminance image generation processing section uses this wide wavelength range image virtually as a luminance image.

In the case of a Bayer pattern with red, green and blue primary color filters and without the color filter C1, it is necessary to find estimated values of the red, green and blue primary color components based on color/sensitivity mosaic images obtained via the red, green and blue filters and color mosaic pattern information and sensitivity mosaic pattern information representing the arrangement pattern of the red, green and blue filters first, followed by multiplication of the estimated values by color balance factors, addition of the products for different colors and generation of a luminance image having the sum of the products as a pixel value. However, the first embodiment eliminates the need for such a calculation.

The luminance image generation processing section can also use a composite calculation approach for red, green and blue. For example, estimated values of the red, green and blue primary color components are found based on color/sensitivity mosaic images and color mosaic pattern information and sensitivity mosaic pattern information representing the arrangement pattern of the color filters C1 to C4, followed by multiplication of the found estimated values by color balance factors. Then, the products for the respective colors are added to generate a luminance image having the sum thereof as a pixel value. Here, color balance factors kR, kG and kB are preset values.

The image signal processing section 340 includes an infrared suppression correction processing section 342. The same section 342 generates corrected visible imaging signals SVL* (SR*, SG* and SB*) by correcting the visible imaging signal SVL using the infrared imaging signal SIR (high-sensitivity imaging signal SHS).

The image signal processing section 340 includes a luminance signal processing section 344, color signal processing section 346 and infrared signal processing section 348. The luminance signal processing section 344 generates a luminance signal based on the corrected visible imaging signals SVL* output from the infrared suppression correction processing section 342. The color signal processing section 346 generates color signals (primary color signals and color difference signals) based on the corrected visible imaging signals SVL* output from the infrared suppression correction processing section 342. The infrared signal processing section 348 generates an infrared signal representing an infrared image based on the infrared imaging signal SIR.

In the configuration example according to the first embodiment, the infrared suppression correction processing section 342 for infrared light is provided at the subsequent stage of the sensitivity enhancement correction processing section 341. However, the same section 341 may be provided at the subsequent stage of the infrared suppression correction processing section 342. In this case, the luminance image generation processing section provided in the sensitivity enhancement correction processing section 341 can be shared with the luminance signal processing section 344. Further, the single color image processing section can be shared with the color signal processing section 346.

The imaging signal output from the solid-state imaging element 314 is amplified to a predetermined level by the preprocessing section 332 of the imaging signal processing section 330, and converted from an analog signal to a digital signal by the AD conversion section 334. The infrared components in the digital image signal of the visible components are suppressed by the infrared suppression correction processing section 342. Further, the resultant signal is divided into red, green and blue separate color signals as necessary (particularly, if complementary color filters are used as the color filters C2 to C4) by the luminance signal processing section 344 and color signal processing section 346. Then, each of the resultant signals is converted, for example, into a luminance signal or color signal or a composite video signal obtained by combining the luminance signal and color signal. The infrared imaging signal SIR is corrected by the infrared signal processing section 348 using the visible imaging signals SVL.

The infrared suppression correction processing section 342 need only be able to correct the visible imaging signals SVL using the infrared imaging signal SIR. Where the same section 342 is provided is not limited to the above configuration. For example, the infrared suppression correction processing section 342 may be provided between the AD conversion section 334 and pixel signal correction processing section 336 adapted to perform shading correction and correction for pixel defects so that the impact of infrared light can be suppressed before shading correction and correction for pixel defects.

Alternatively, the infrared suppression correction processing section 342 may be provided between the preprocessing section 332 and AD conversion section 334 so that infrared light can be suppressed after preprocessing such as black level adjustment, gain adjustment and gamma correction. Still alternatively, the infrared suppression correction processing section 342 may be provided between the solid-state imaging element 314 and preprocessing section 332 so that infrared light can be suppressed prior to preprocessing such as black level adjustment, gain adjustment and gamma correction.

Thanks to these configurations, the imaging device 300 captures an optical image containing the infrared light IR and representing the subject Z by means of the imaging optical system 302, thus allowing the optical image to be captured into the imaging section 310 without separation into an infrared image (near infrared light optical image) and visible image (visible optical image). The imaging signal processing section 330 converts the infrared image and visible image respectively into video signals, followed by predetermined signal processing (e.g., separation into red, green and blue component color signals). Finally, the color image signal and infrared image signal or mixed image signal obtained by combining the two signals are output.

For example, the imaging optical system 302 includes an imaging lens made of an optical material such as quartz or sapphire that can transmit light ranging in wavelength from 380 nm to 2200 nm, thus capturing an optical image containing the infrared light IR and gathering light to form an image on the solid-state imaging element 314.

The color filter C1 is designed to provide a high-sensitivity signal with higher light utilization efficiency than the signals obtained via the color filters C2 to C4. The infrared imaging signal SIR serves also as the high-sensitivity imaging signal SHS (HS: High Sensitivity).

The imaging device 300 according to the present embodiment can capture an image containing a mixture of the visible light VL and light other than visible light (infrared light IR in the present example) although depending on the type of signal processing selected. In some cases, the imaging device 300 can output two images separately, one having only the visible light VL and another having only the infrared light IR.

This ensures immunity from the effect of the infrared light IR during capture of a monochrome or color image at daytime and permits imaging using the infrared light IR at night. The imaging device 300 can also output an image having only the infrared light IR that remains unaffected by the visible light VL. Even in this case, the imaging device 300 can provide an image having only the infrared light IR unaffected by the visible light VL at daytime.

A monochrome image having only visible light can be obtained by combining signals at different wavelengths (of different colors). This makes it possible to implement an application using two monochrome images, one containing infrared components and another containing only visible light obtained from the wide wavelength range pixel 12A. Further, an image having only infrared components can be extracted by taking the difference between the two monochrome images.

It is also possible to compare two images, an infrared image obtained by emitting light at a specific wavelength in the infrared range from the light-emitting section 322 and a normal image (which may contain infrared components of solar light at wavelengths other than the specific wavelength) obtained without emitting any light at the specific wavelength from the light-emitting section 322. In this case, information derived from light at the specific wavelength can be separated with high accuracy at both daytime and nighttime, thus allowing for highly accurate distance measurement.

As for the distance measurement technique based on an infrared image obtained by emitting light at the specific wavelength from the light-emitting section 322, it is only necessary to use the technique described in Patent Document 3 (referred to as FIG. 3 of Patent Document 3).

It is possible to simultaneously receive not only an image visible to the eye but also another image invisible to the eye associated therewith. In addition, imaging is possible by switching emission and no emission of light at the specific wavelength from the light-emitting section 322, thus providing the first camera system of its kind.

### Second Embodiment

In the second embodiment, a special band-pass filter is provided on the incident surface of the imaging section in addition to the first embodiment using the light-emitting section 322 adapted to emit light at the specific wavelength. This band-pass filter, provided in the imaging optical system on the photoreception side, is designed to transmit the wavelength components used for the light source, an example of the first wavelength range, and blocks all other infrared wavelengths components. Further, the second embodiment may assume various forms depending on how the visible range, an example of the second wavelength range, is treated.

A specific description will be given below. It should be noted that, unless otherwise specified, the first wavelength range is, for example, an infrared range beyond 680 nm or 750 nm in wavelength. Further, unless otherwise specified, the term “reception optical path on the photoreception side” refers to the optical path of the imaging optical system from the imaging lens to the surface of the detection section of the solid-state imaging element 314, i.e., the imaging device. Still further, the term “the surface of the detection section of the solid-state imaging element 314” refers to the main body of the device excluding components such as the color filters (color filter group 312) and on-chip microlenses.

### First Example

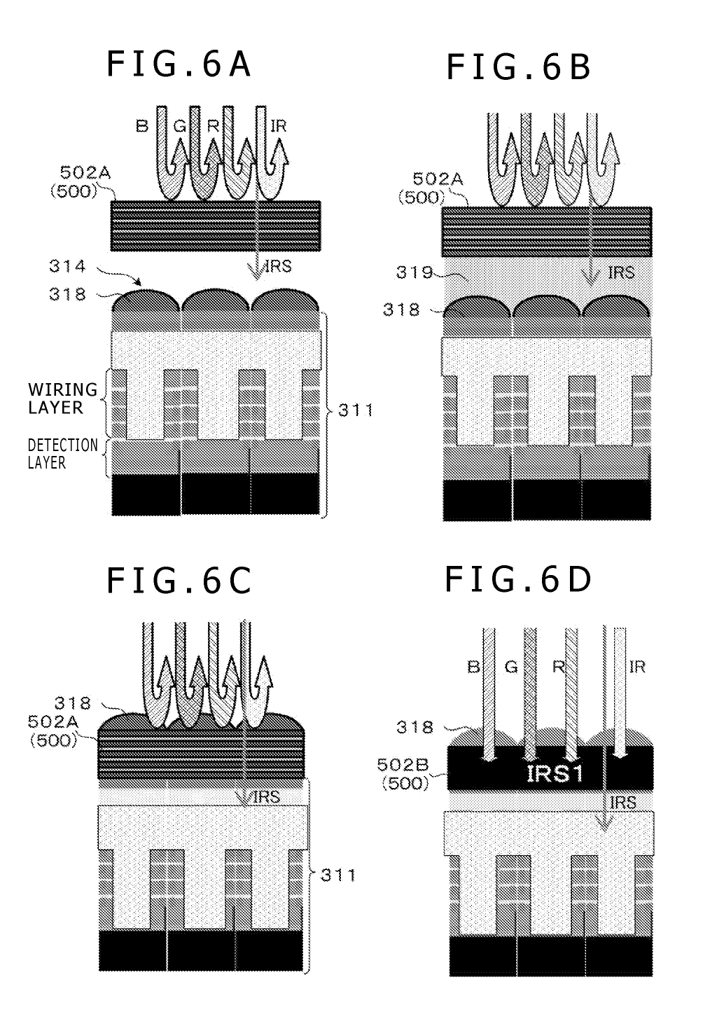

FIGS. 6A to 6D are diagrams illustrating a first example of a combination of a light source (light at a specific wavelength), optical filter section and imaging device structure.

The first example is characterized in that a light source (light-emitting section 322) is used that emits light containing one or more specific wavelength components in the infrared range, and that an optical band-pass filter 502 is provided in the photoreception optical path on the photoreception side as the optical filter section 500 to remove most of the wavelengths other than the specific wavelength. In the imaging optical system on the photoreception side, the special optical band-pass filter 502 is provided to transmit only a specific band of wavelengths of all the light emitted from the light source and cuts off all other infrared light and visible light. In order to reduce noise components of solar light, the optical band-pass filter 502 does not have to transmit wavelengths in the infrared range other than absorbed solar wavelengths. In the arrangement of the first example, the color filter group 312 made up of blue, green and red filters is not provided over the pixels of the solid-state imaging element 314 so that the pixels receive light in the visible range (entire range of wavelengths for blue, green and red components).

Typically, the above-described solar light corresponds to disturbance light. In this case, absorbed solar wavelengths correspond to the specific wavelengths. However, “specific wavelengths” are not necessarily limited thereto and may be given wavelengths inside or outside the infrared range. For example, whether indoors or outdoors, if imaging is conducted under influence of a mercury or sodium lamp, these light sources may be another example of disturbance light components as with solar light. Further, in an environment such as indoors where there is almost no need to consider entry of solar light, undesired components other than solar light (and illumination light such as fluorescent or incandescent lamp) may be present as still another example of disturbance light components.

Accordingly, if, in these cases, one of the disturbance light components is a low energy wavelength that is relatively lower in energy level than other wavelengths (not limited to one point but may extend over a given range: the same holds true hereinafter), this low energy wavelength corresponds to a specific wavelength. On the other hand, there may be not just one but a plurality of low energy wavelengths in the disturbance light components. In this case, each of the plurality of low energy wavelengths is a “specific wavelength.” The same holds true in these regards for other examples which will be described later.

For example, FIG. 6A illustrates a case in which an optical band-pass filter 502A is provided as an optical element separate from the solid-state imaging element 314 when the special optical band-pass filter 502 is provided in the optical path of the imaging optical system. On the other hand, FIG. 6B illustrates a configuration in which the special optical band-pass filter 502 is provided integrally on the solid-state imaging element 314 when the same filter 502 is provided in the optical path of the imaging optical system. In FIG. 6B, microlenses 318 are provided in an on-chip manner on a device main body 311 of the solid-state imaging element 314. The optical band-pass filter 502 is provided above the microlenses 318 via a protective layer 319 that is transparent to at least the specific wavelength. In FIGS. 6C and 6D, the microlenses 318 and optical band-pass filter 502 are arranged in reverse order to do without the protective layer 319 (or use the same layer 319 that is extremely thin).

The optical band-pass filter 502 need only absorb or reflect light in the visible range in addition to the wavelengths other than the specific wavelengths in the infrared range. For example, the filters shown in FIGS. 6A to 6C rely on “reflection.” Although described in detail later, the optical band-pass filter 502A is used that is made up of a combination of two or more types of multi-layer film filters having different filtering characteristics (layered structure).

The filter shown in FIG. 6D relies on “absorption,” and an optical band-pass filter 502B is used. An infrared filter IRS1 is used as the optical band-pass filter 502B and transmits only the specific wavelength in the infrared range and absorbs all other specific wavelengths in the infrared range.

The infrared filter IRS1 need only be implemented by combining two color filters, one high-pass and another low-pass, each of whose cutoff wavelength is set around the specific wavelength, as with the basic philosophy behind the manufacturing method of, for example, the special optical band-pass filter 502 which will be described later. The same filter IRS1 may also be implemented by selecting materials based on the same philosophy as that for the red, green and blue color filters.

It should be noted that even if the detection section receives light at wavelengths which the imaging device does not have photoelectric conversion sensitivity, no photoelectric conversion takes place. Therefore, the infrared filter IRS1 need only transmit infrared light at wavelengths (only specific wavelengths particularly in the present example) below which the imaging device does not have photoelectric conversion sensitivity. Whether the same filter IRS1 transmits light at wavelengths which the imaging device does not have photoelectric conversion sensitivity does not matter. The same holds true in this regard for various types of optical members including other infrared filters and optical band-pass filters.

The arrangement in the first example is applied, for example, as the solid-state imaging element 314 (photoelectric conversion element), photoreception system and camera system. Therefore, for example, a camera system can be built that serves two purposes, namely, capture of a monochrome image using only the same wavelength component as the wavelength of the light source (specific wavelength) in the infrared range, and acquisition of distance measurement information by emitting infrared light (invisible light) at the specific wavelength from the light source, by switching between image capture and information acquisition. In order to obtain an image consisting of infrared light at the specific wavelength as a normal image, infrared light (invisible light) at the specific wavelength is not emitted from the light source. In order to obtain a measurement image representing distance measurement information, on the other hand, all the pixels are used to obtain light at the specific wavelength (hereinafter also referred to as “specific wavelength light”) to be irradiated onto the subject and obtain distance information. An image representing distance information based on infrared light at the specific wavelength emitted from the light source can be extracted with high accuracy by comparing the normal image and measurement image obtained by switching (typically, taking the difference between the two images).

That is, the arrangement according to the second embodiment is not limited to simultaneous acquisition of color images as in a fifth example which will be described later. Providing the special optical band-pass filter 502 adapted to transmit the specific wavelength band and cut off all other wavelengths of infrared light and visible light in the imaging optical system on the photoreception side makes it possible to use all the pixels for obtaining an image based on the specific wavelength (not limited to the specific wavelength irradiated onto the subject from the light-emitting section 322).

In the camera system to which the first example is applied, for example, the visible components (components R, G and B shown in FIGS. 6A to 6D) reflected by the subject are reflected by the optical band-pass filter 502. Therefore, these components are not converted into electric signals by the solid-state imaging element 314. On the other hand, the infrared components (components IR in FIGS. 6A to 6D) other than the specific wavelength component in the infrared range are removed by the optical band-pass filter 502. Therefore, these components are not converted into electric signals by the solid-state imaging element 314. However, whether emitted from the light source and reflected by the subject, the specific wavelength components (components IRS in FIGS. 6A to 6D) in the infrared range pass through the optical band-pass filter 502 and are incident to the solid-state imaging element 314 where they are converted into electric signals.

In the first example, it is possible to obtain either a monochrome image based on a specific wavelength light, whether emitted from the light-emitting section 322, or a measurement image based on the specific wavelength light (infrared light in this case) emitted from the light source (that is, emitted from the light-emitting section 322) and irradiated onto the subject by switching. Alternatively, it is possible to simultaneously obtain two images. As a result, distance measurement is possible using a signal of the specific wavelength light irradiated onto the subject. Saturation of the photoreceiving element can be avoided thanks to reduction in undesired infrared components other than the specific wavelength component.

### Second Example

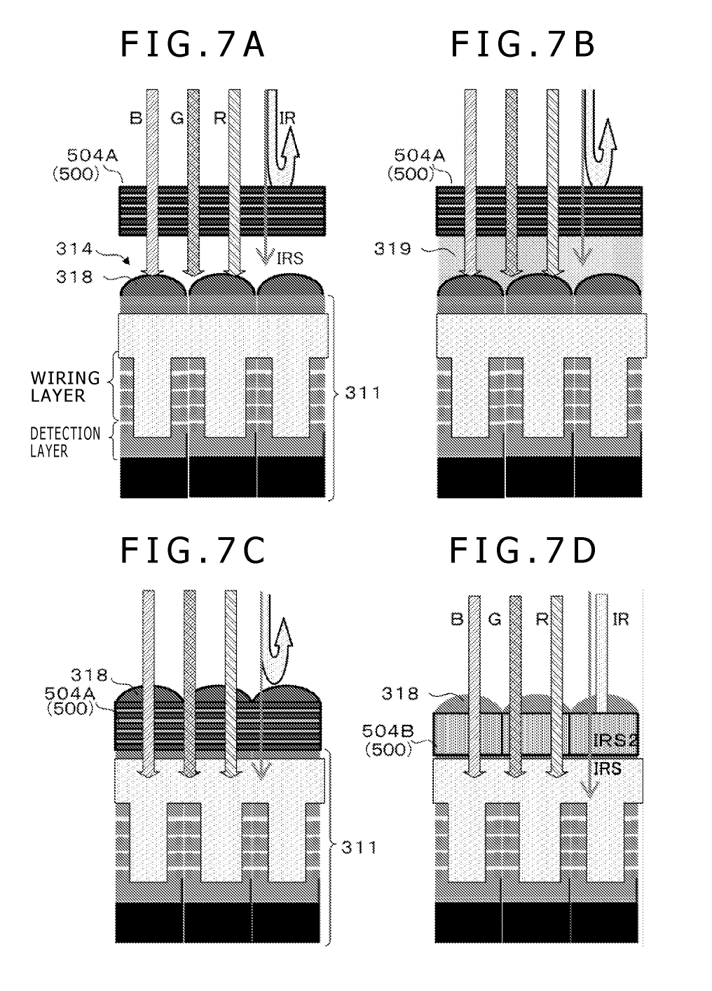

FIGS. 7A to 7D are diagrams illustrating a second example of a combination of a light source (light at a specific wavelength), optical filter section and imaging device structure.

The second example is identical to the first example in that a light source is used that contains one or more specific wavelength components in the infrared range, and is characterized in that an optical band-pass filter 504 is provided on the photoreception side as the optical filter section 500 to remove the visible components and most of the wavelengths other than the specific wavelength. The second example is identical to the first example in its light source but different therefrom in its optical filter section 500. The optical band-pass filter 504 can also transmit the components in the visible range, thus acquiring a monochrome image based on light in the visible range.

In addition to transmitting the components in the visible range, the special optical band-pass filter 504 does not have to transmit the wavelengths in the infrared band other than the specific wavelengths to ensure reduced noise components of solar light. In the arrangement of the second example, the color filter group 312 made up of blue, green and red filters is not provided over the pixels of the solid-state imaging element 314 so that the pixels receive all light in the visible range.

For example, FIG. 7A is associated with FIG. 6A and illustrates a case in which the optical band-pass filter 504 is provided as an optical element separate from the solid-state imaging element 314 when the special optical band-pass filter 504 is provided in the optical path of the imaging optical system. On the other hand, FIG. 7B is associated with FIG. 6B and illustrates a configuration in which the special optical band-pass filter 504 is provided integrally on the solid-state imaging element 314 when the same filter 504 is provided in the optical path of the imaging optical system. FIGS. 7C and 7D are associated respectively with FIGS. 6C and 6D and illustrate structures in which the microlenses 318 and optical band-pass filter 504 are arranged in reverse order to do without the protective layer 319 (or use the same layer 319 that is extremely thin).

Although described in detail later, the optical band-pass filter 504 need only transmit light in the visible range and the specific wavelength component in the infrared range and absorb or reflect light at all other wavelengths. For example, the filters shown in FIGS. 7A to 7C rely on “reflection.” An optical band-pass filter 504A is used that is made up of a combination of two or more types of multi-layer film filters having different filtering characteristics (layered structure).

The filter shown in FIG. 7D relies on “absorption,” and an optical band-pass filter 504B is used. An infrared filter IRS2 is used as the optical band-pass filter 504B and absorbs light other than that in the visible range and the specific wavelength in the infrared range. The infrared filter IRS2 need only be implemented by combining two color filters, one high-pass and another low-pass, each of whose cutoff wavelength is set around the specific wavelength, as with the basic philosophy behind the manufacturing method of, for example, the special optical band-pass filter 504 which will be described later. Although not illustrated, the optical band-pass filter 504B may include the all-pass white filter W to transmit light in the visible range in the area for the pixels for visible light (visible pixels) and the infrared filter IRS2 to absorb light in the infrared range other than the specific wavelength in the area for the infrared light pixel.

The arrangement in the second example is also applied, for example, as the solid-state imaging element 314 (photoelectric conversion element), photoreception system and camera system. For example, a camera system can be built that simultaneously allows for capture of a monochrome image (example of normal image) using visible light containing the same wavelength component as the wavelength of the light source in the infrared range and acquisition of a measurement image representing distance measurement information by emitting infrared light (invisible light) at the specific wavelength from the light source or either monochrome image capture or measurement image acquisition by switching between these two options. Whether image capture is simultaneous with acquisition of distance information, the solid-state imaging element 314 is devoid of the color filter group 312 made up of blue, green and red filters (color filters 14) on its pixels and therefore receives all visible light, thus acquiring an image having significantly bright luminance information (monochrome image). More specifically, in the case of the configuration shown in FIG. 7D, each of the pixels is unable to distinguish between visible light and light at the specific wavelength in the infrared range. As a result, a monochrome image is obtained that contains the components in the visible band and the component of light at the specific wavelength in the visible range.

For example, in order to obtain a visible image (natural light image) by switching between image capture and acquisition of distance measurement information, infrared light (invisible light) at the specific wavelength from the light source is not emitted from the light source. In order to obtain distance measurement information, on the other hand, all the pixels are used to obtain both light at the specific wavelength to be irradiated onto the subject and visible light and acquire distance information mixed in a visible image. Further, an image based only on infrared light at the specific wavelength emitted from the light source can be extracted by taking the difference between the normal and measurement images obtained by switching.

In the camera system to which the second example is applied, for example, the visible components (components R, G and B shown in FIGS. 7A to 7D) reflected by the subject pass through the optical band-pass filter 504, to be incident on the pixels of the solid-state imaging element 314 where the components are converted into electric signals. Whether emitted from the light source and reflected by the subject, the specific wavelength components in the infrared range (components IRS in FIGS. 7A to 7D) also pass through the optical band-pass filter 504, to be incident on the solid-state imaging element 314 where the components are converted into electric signals. However, the infrared components other than the specific wavelength component in the infrared range (component IR in FIGS. 7A to 7D) are removed by the optical band-pass filter 504. As a result, these components are not converted into electric signals by the pixels of the solid-state imaging element 314.

This second example differs from a second modification example for the second example which will be described later in that it is substantially impossible to distinguish between the pixels for visible light and the pixel for the infrared light IRS. In the second modification example, it is possible to make this distinction. That is, if the solid-state imaging element 314 or camera system is configured as described above, the blue, green and red wavelength components pass through the optical band-pass filter 504 in the imaging optical system and are received by the visible pixels (as well as the infrared pixel) of the solid-state imaging element 314 where the components are converted into electric signals with no distinction between colors. The majority of light in the infrared range does not pass through the optical band-pass filter 504 in the imaging optical system and therefore is not converted into an electric signal. Light at the specific wavelength irradiating onto the subject passes through the special optical band-pass filter 504 in the imaging optical system and is received by the infrared light pixel (as well as the visible pixels) and converted into an electric signal.

Light from the light source irradiated onto the subject may be collected by the pixels and converted into an electric signal, possibly introducing noise to the luminance component representing a monochrome visible image. However, a significantly large amount of the original visible component (composite light having blue, green and red) is converted into an electric signal by the visible pixels. Therefore, the impact of noise on the luminance component is extremely limited and negligible.

In the second example, it is possible to obtain either a monochrome image of the visible band (specifically, containing the specific wavelength light in the infrared range) or a measurement image based on the specific wavelength light (infrared light in this case) emitted from the light source (that is, emitted from the light-emitting section 322) by switching between the two options or obtain both images simultaneously, thus allowing for distance measurement using a signal of the specific wavelength light irradiated onto the subject.

Although not illustrated, a shallow area of the semiconductor layer may be used as an effective area for the visible pixels, with a deep area of the semiconductor layer used as an effective area for the infrared light pixel, as described above in relation to the sensitivity enhancement measure for the infrared light pixel. In this case, the pixels can distinguish between visible light and light at the specific wavelength in the infrared range, thus acquiring a monochrome image containing only the components in the visible range for the visible pixels.

### Modification Examples of the Second Example

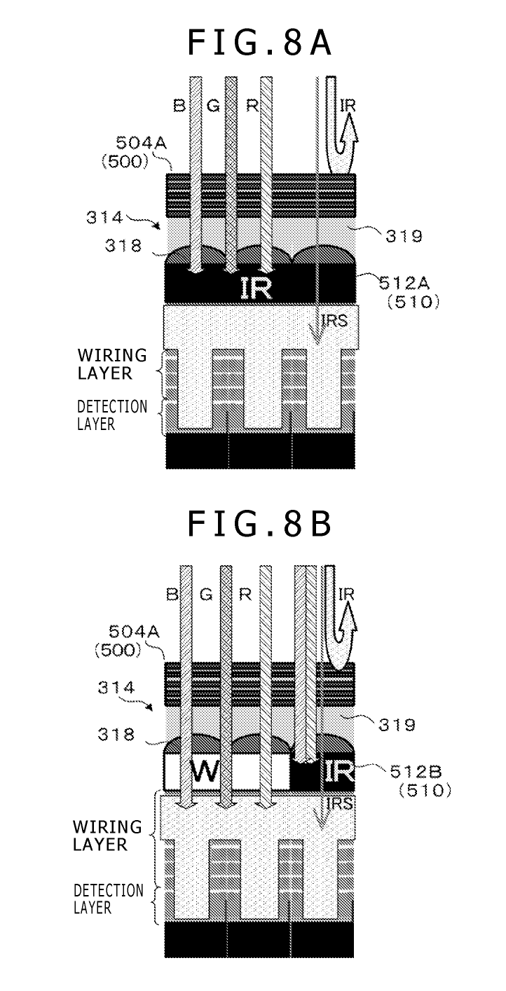

FIGS. 8A and 8B are diagrams illustrating modification examples of the second example of a combination of a light source (light at a specific wavelength), an optical filter section and an imaging device structure.

FIG. 8A illustrates a first modification example of the second example. The optical band-pass filter 504 in the first modification example relies on “reflection.” In addition to the same filter 504, a color filter section 510 is provided in the optical path of the imaging optical system. The color filter section 510 shown in FIG. 8A is an example of a visible cutoff filter 512A provided in an on-chip fashion over the entire surface of the solid-state imaging element 314. The visible cutoff filter 512A transmits the specific wavelength and “absorbs” light in the visible band. Although FIG. 8A illustrates a modification example of the configuration shown in FIG. 7B, the same modification is applicable to other configurations.

In the first modification example of the second example, the optical filter section 500 includes a combination of the optical band-pass filter 504 and visible cutoff filter 512A. An infrared filter IR adapted to absorb visible light and transmit infrared light is used as the visible cutoff filter 512A. The same filter IR need only remove the visible wavelengths by absorption or reflection and transmit at least the specific wavelength in the infrared range. That is, there is no need for the infrared filter IR to transmit only the specific wavelength in the infrared range. The infrared filter IR need only be an ordinary color filter for infrared light adapted to transmit only the infrared band (containing at least the specific wavelength range).

In the case of the first modification example of the second example, the visible components (components R, G and B shown in FIGS. 8A and 8B) reflected by the subject pass through the optical band-pass filter 504 but are absorbed by the visible cutoff filter 512A. As a result, these components are not converted into electric signals by the pixels of the solid-state imaging element 314. Therefore, the same information as in the first example is obtained by the solid-state imaging element 314. For example, a camera system can be built that allows for either capture of a monochrome image (infrared image at the specific wavelength) using the same wavelength component as the wavelength of the light source in the infrared range or acquisition of a distance measurement information by emitting infrared light (invisible light) at the specific wavelength from the light source by switching between these two options.

FIG. 8B illustrates a second modification example of the second example. The optical band-pass filter 504A in the second modification example relies on “reflection.” In addition to the optical band-pass filter 504A, the color filter section 510 is provided in the optical path of the imaging optical system. The color filter section 510 shown in FIG. 8B is an example of a visible cutoff filter 512B provided in an on-chip fashion over the solid-state imaging element 314. The visible cutoff filter 512B transmits the specific wavelength and “absorbs” light in the visible band. In the second modification example of the second example, therefore, the same information as in the second example is obtained by the solid-state imaging element 314. The visible cutoff filter 512B differs from the visible cutoff filter 512A in that the infrared filter IR is provided only in the area for the infrared light pixel to “absorb” light in the visible band. Although FIG. 8B illustrates a modification example of the configuration shown in FIG. 7B, the same modification is applicable to other configurations.

In the second modification example of the second example, the optical filter section 500 includes a combination of the optical band-pass filter 504A and visible cutoff filter 512B. The visible cutoff filter 512B includes the all-pass white filter W to transmit light in the visible band in the area for the visible pixels and the infrared filter IR to absorb visible light and transmit infrared light in the area for the infrared light pixel. There is no need for the infrared filter IR to transmit only the specific wavelength in the infrared range. The infrared filter IR need only be an ordinary color filter for infrared light adapted to transmit only the infrared band (containing at least the specific wavelength range).

It should be noted that the all-pass white filter W of the visible cutoff filter 512B is provided as a visible transmission material to deal with possible structural difficulties in device manufacture (due, for example, to the arrangement of the on-chip microlenses) that would arise if the all-pass white filter W was not provided. Therefore, the all-pass white filter W is not absolutely essential in the area for the visible pixels if there are no manufacturing problems.

Providing the visible cutoff filter 512B in the color filter section 510 allows for the pixels to distinguish between visible and infrared images. This makes is possible for the single solid-state imaging element 314 to obtain a monochrome image and infrared information at the same time. Thanks to the optical band-pass filter 504A, the majority of undesired components in the infrared range can be cut off, thus avoiding saturation of the infrared light pixel.

The color filter section 510 has the all-pass white filter W in the area for the visible pixels. In reality, however, blue, green and red filters are not provided over the visible pixels. As a result, the visible pixels receive all visible light. Therefore, the second modification example of the second example makes it possible to obtain a significantly bright luminance information image (monochrome image) and distance measurement information at the same time.

### Third Example

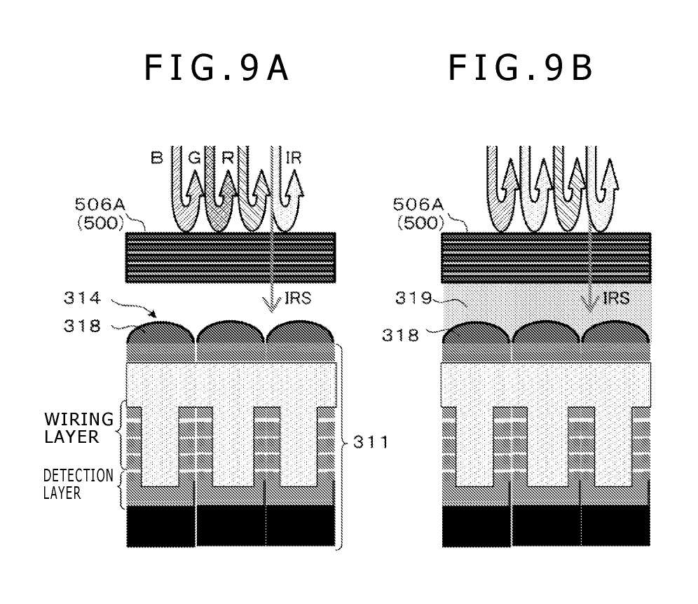

FIGS. 9A and 9B are diagrams illustrating a third example of a combination of a light source (light at a specific wavelength), optical filter section and imaging device structure.

The third example is an example of application to a case in which the “specific wavelength range” in the first example is absorbed solar wavelengths. Each of a plurality of absorbed solar wavelengths corresponds to the “specific wavelength range.” The same holds true in this regard for other examples which will be described later.

A light source adapted to emit light containing wavelength components around 760 nm, 940 nm, 1130 nm or 1400 nm, i.e., absorbed solar wavelengths, is used as the light-emitting section 322. An optical band-pass filter 506 adapted to remove wavelengths other than that of the light source is provided on the photoreception side (in the photoreception optical path). The optical band-pass filter 506 is comparable to the optical band-pass filter 502 in the first example.

For example, FIG. 9A is associated with FIG. 6A and illustrates a case in which the optical band-pass filter 506A is provided as an optical element separate from the solid-state imaging element 314 when the special optical band-pass filter 506 is provided in the optical path of the imaging optical system. On the other hand, FIG. 9B is associated with FIG. 6B and illustrates a case in which the optical band-pass filter 506A is provided integrally on the solid-state imaging element 314 when the special optical band-pass filter 506 is provided in the optical path of the imaging optical system. Although not illustrated, structures respectively associated with FIGS. 6C and 6D may be selected in which the microlenses 318 and optical band-pass filter 506 are arranged in reverse order to do without the protective layer 319 (or use the protective layer 319 that is extremely thin).

In FIG. 9A, the optical band-pass filter 506A is used in combination with a light source adapted to emit light containing wavelength components including those around 940 nm, i.e., absorbed solar wavelengths. FIG. 9A illustrates a case in which a filter separate from the solid-state imaging element 314 and adapted to transmit the wavelength components around 940 nm is used as the optical band-pass filter 506A. The solid-state imaging element 314 is devoid of the color filter group 312 (has no color filters), making the solid-state imaging element 314 a monochrome imaging device.

In FIG. 9B, the optical band-pass filter 506A is used in combination with a light source adapted to emit light containing wavelength components including those around 940 nm, i.e., absorbed solar wavelengths. FIG. 9B illustrates a case in which the optical band-pass filter 506A adapted to transmit wavelength components around 940 nm is provided in an on-chip fashion over the solid-state imaging element 314. The solid-state imaging element 314 is devoid of the color filter group 312 (has no color filters), making the solid-state imaging element 314 a monochrome imaging device.

### Fourth Example

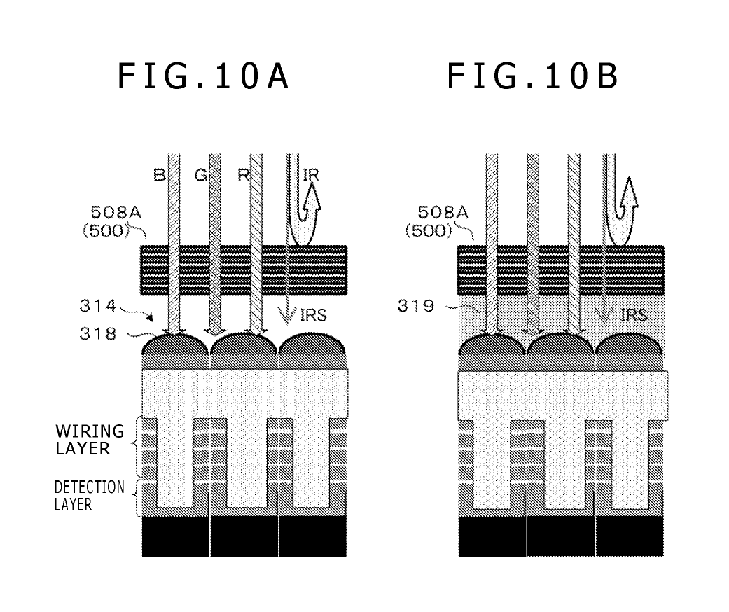

FIGS. 10A and 10B are diagrams illustrating a fourth example of a combination of a light source (light at a specific wavelength), optical filter section and imaging device structure.

The fourth example is an example of application to a case in which the “specific wavelength range” in the second example is absorbed solar wavelengths. A light source adapted to emit light containing wavelength components around 760 nm, 940 nm, 1130 nm or 1400 nm, i.e., absorbed solar wavelengths, is used as the light-emitting section 322. An optical band-pass filter 508 adapted to remove wavelengths other than visible light and the wavelength of the light source is provided on the photoreception side (in the photoreception optical path). The optical band-pass filter 508 is equivalent to the optical band-pass filter 504 in the second example.

For example, FIG. 10A is associated with FIG. 7A and illustrates a case in which an optical band-pass filter 508A is provided as an optical element separate from the solid-state imaging element 314 when the special optical band-pass filter 508 is provided in the optical path of the imaging optical system. On the other hand, FIG. 10B is associated with FIG. 7B and illustrates a case in which the optical band-pass filter 508A is provided integrally on the solid-state imaging element 314 when the special optical band-pass filter 508 is provided in the optical path of the imaging optical system. Although not illustrated, structures respectively associated with FIGS. 7C and 7D may be selected in which the microlenses 318 and optical band-pass filter 508 are arranged in reverse order to do without the protective layer 319 (or use the protective layer 319 that is extremely thin).

In FIG. 10A, the optical band-pass filter 508A is used in combination with a light source adapted to emit light containing wavelength components including those around 940 nm, i.e., absorbed solar wavelengths. FIG. 10A illustrates a case in which a filter separate from the solid-state imaging element 314 and adapted to transmit the wavelength components around 940 nm is used as the optical band-pass filter 508A. The solid-state imaging element 314 is devoid of the color filter group 312 (has no color filters), making the solid-state imaging element 314 a monochrome imaging device.

In FIG. 10B, the optical band-pass filter 508A is used in combination with a light source adapted to emit light containing wavelength components including those around 940 nm, i.e., absorbed solar wavelengths. FIG. 10B illustrates a case in which the optical band-pass filter 508A adapted to transmit wavelength components around 940 nm is provided in an on-chip fashion over the solid-state imaging element 314. The solid-state imaging element 314 is devoid of the color filter group 312 (has no color filters), making the solid-state imaging element 314 a monochrome imaging device.

Although not illustrated, the fourth example may be modified in the same manner as with the first or second modification example for the second example.

In the fourth example, the wavelength of the light source is matched to the specific wavelength around 760 nm, 940 nm, 1130 nm or 1400 nm of solar light, thus avoiding noise components in the infrared band caused by the outdoor solar light. Light at one of these specific wavelengths is irradiated onto the subject from the light-emitting section 322. At the same time, the optical band-pass filter 508 is provided as an example of an optical element, i.e., an infrared cutoff filter adapted to cut off noise components in the infrared range and transmit the wavelength components of the visible band and the specific wavelength band from the light source, thus avoiding detection of the components other than the specific wavelength in the infrared range by the detection section and resolving the problem of saturation.

### Fifth Example

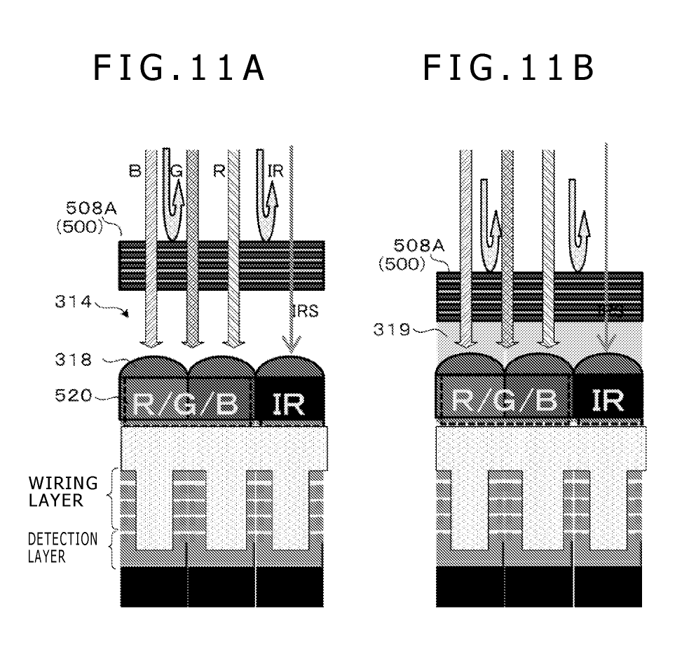

FIGS. 11A and 11B are diagrams illustrating a fifth example of a combination of a light source (light at a specific wavelength), optical filter section and imaging device structure.

The fifth example is a modification example of the second and fourth examples that allow for acquisition of a normal image of visible light. The modification is designed to separately receive different colors in the visible band, thus allowing for color image capture. Therefore, a color filter adapted to transmit different wavelengths for different colors in the visible range is provided in the area for the visible pixels, and a color filter adapted to absorb or reflect visible light and transmit at least the specific wavelength component in the infrared range is provided in the area for the infrared light pixel for the specific wavelength component.

For example, FIG. 11A is associated with FIG. 7A and FIG. 10A and illustrates a case in which the special optical band-pass filter 508 is provided as an optical element separate from the solid-state imaging element 314 when the optical band-pass filter 508 is provided in the optical path of the imaging optical system. On the other hand, FIG. 11B is associated with FIG. 7B and FIG. 10B and illustrates a configuration in which the special optical band-pass filter 508 is provided integrally on the solid-state imaging element 314 when the optical band-pass filter 508 is provided in the optical path of the imaging optical system. Although not illustrated, structures respectively associated with FIGS. 7C and 7D may be selected in which the microlenses 318 and optical band-pass filter 508 are arranged in reverse order to do without the protective layer 319 (or use the protective layer 319 that is extremely thin).

Although the basic configuration of the fifth example described above is identical to those of the second and fourth examples, a color filter section 520 is provided that has color filters for color separation (color filter group 312) in the area for the visible pixels to separately receive different colors in the visible band. As with the second and fourth examples, the optical band-pass filter 504 or 508 is provided in the imaging optical system on the photoreception side to transmit visible light and light at the specific wavelength emitted from the light source in the infrared range and cut off all other infrared light.

If the visible pixels adapted to capture a color image include, for example, blue, green and red pixels to obtain a color image, not only pixels having a color filter adapted to absorb or reflect the components other than the wavelength of interest but also an infrared light pixel adapted to detect light at the specific wavelength irradiated onto the subject and obtain distance information are provided. The infrared filter IR is provided over the infrared light pixel to remove the wavelengths of visible components by absorption or reflection and transmit at least the specific wavelength in the infrared range.

The color filter section 520 is comparable to the color filter section 510 and particularly to the visible cutoff filter 512B in the second modification example of the second example shown in FIG. 8B. As a configuration, the color filter section 520 includes a color separation filter R/G/B rather than the all-pass white filter W of the visible cutoff filter 512B. The color separation filter R/G/B has color filters for blue (B), green (G) and red (R) arranged therein. The color filter section 520 includes the infrared filter IR adapted to absorb visible light and transmit infrared light in the area for the infrared light pixel.

A description will be given below of a modification example of the fourth example. This modification example focuses on the solar wavelengths reaching the ground, taking advantage, for example, of the specific wavelength band around 760 nm, 940 nm, 1130 nm or 1400 nm where solar light intensity is significantly small. Then, the camera system to be implemented uses, as the light-emitting section 322, a light source adapted to irradiate light containing the wavelength components in one of the four specific wavelength bands in the infrared band at or beyond 750 nm to the subject.

If the solid-state imaging element 314 or camera system is configured as described above, the blue, green and red wavelength components pass through the optical band-pass filter 508 in the imaging optical system. As a result, the color components of a color image are received respectively by the color filters provided over the solid-state imaging element 314 in the same manner as in an existing imaging element or camera system, thus allowing for these components to be converted into electric signals. In the infrared light pixel having the infrared filter IR adapted to remove the wavelengths of visible components by absorption or reflection, on the other hand, the blue, green and red wavelength components are not converted into electric signals.

In the acquisition of distance measurement information by irradiating light at the specific wavelength from the light-emitting section 322, the majority of light other than the specific wavelength component in the infrared wavelength band of solar light irradiated onto the subject does not pass through the optical band-pass filter 504 or 508 in the imaging optical system. As a result, such light is not converted into an electric signal. On the other hand, the specific wavelength component irradiated onto the subject passes through the optical band-pass filter 504 or 508 in the imaging optical system and is received by the infrared light pixel having the infrared filter IR adapted to remove the wavelengths of visible components by absorption or reflection, thus allowing for this component to be converted into an electric signal.

Light at the specific wavelength irradiated onto the subject may be collected by the visible pixels and converted into an electric signal depending on the spectral characteristic of the color separation filter R/G/B for color image, possibly introducing noise to the color components of the color image. However, a significantly large amount of the original visible components (blue, green and red light) is converted into an electric signal by the color pixels. Therefore, the impact of noise on the color components is extremely limited and negligible. At a dark location, light irradiated onto the color separation filter R/G/B is converted into an electric signal. However, the impact of light at the specific wavelength can be suppressed by calculating differences such as R-IR·α, G-IR·β and B-IR·γ.

If the optical filter section 500 and color filter section 520 are configured as in the fifth example, the solid-state imaging element 314 provides a color image and infrared information at the same time. That is, the color filter section 520 distinguishes between the visible pixels (particularly, color pixels) and infrared light pixel, thus allowing for a color image and a measurement image based on light at the specific wavelength from the light source adapted to irradiate light onto the subject to be obtained at the same time. Therefore, distance measurement is possible outdoors at daytime using a signal of light at the specific wavelength irradiated onto the subject.

At an outdoor location, of solar light reaching the ground, that around 760 nm, 940 nm, 1130 nm and 1400 nm is absorbed primarily by moisture in the atmosphere. Irradiating light at one of these specific wavelengths onto the subject and providing the optical band-pass filter 506 adapted to transmit the reflected light ensures significant improvement in S/N ratio (Signal-Noise ratio) which would otherwise be degraded by direct disturbance. If the solid-state imaging element 314 or imaging system is configured as described above, a signal with minimal disturbance noise can be obtained outdoors. The reduction in undesired incident solar light components other than the specific wavelength solves the problem of saturation, thus allowing for highly accurate distance measurement and object detection not only indoors but also under the sun.

### Sixth Example

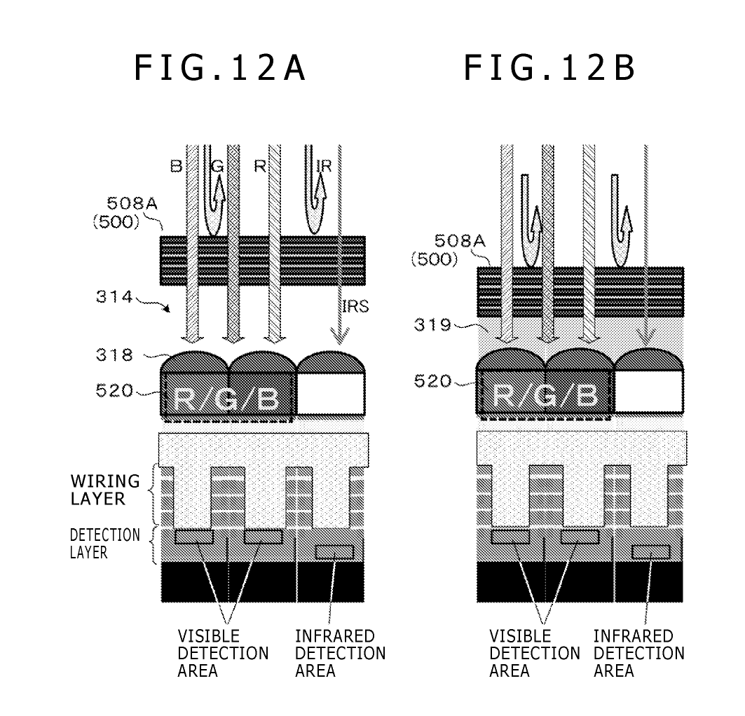

FIGS. 12A and 12B are diagrams illustrating a sixth example of a combination of a light source (light at a specific wavelength), optical filter section and imaging device structure. The sixth example is a modification example of the fifth example. FIG. 12A illustrates an example of application to the configuration shown in FIG. 11A, and FIG. 12B an example of application to the configuration shown in FIG. 11B. In the sixth example, the color filter section 520 is devoid of the infrared filter IR over the infrared light pixel. It should be noted that although a color imaging configuration having the color filter section 520 is shown in this example, the same philosophy is applicable to a monochrome imaging configuration without the color filter section 520.

In this case, there is a concern that visible components may also be detected by the infrared light pixel. As a countermeasure, a deep area of the semiconductor layer is used as an effective area for the infrared light pixel in the sixth example as described in relation to the sensitivity enhancement measure for the infrared light pixel.

That is, the sixth example focuses on the fact that infrared light wavelengths are converted into electric signals at a deeper area in the semiconductor (e.g., silicon) than visible light. As a result, the infrared filter IR is not provided in the color filter section 520. No photoelectric conversion takes place at the depth where visible wavelengths are absorbed. Instead, photoelectric conversion takes place at the depth where infrared light wavelengths are absorbed. This makes it possible to obtain distance information by detecting light at the specific wavelength irradiated onto the subject.

It should be noted that if the infrared filter IR is not provided in the color filter section 520, it may be structurally difficult to manufacture the device (due, for example, to the arrangement of the on-chip microlenses). In order to deal with these difficulties, a material may be used instead that is easy to use in the manufacturing process and transmits light at the specific wavelength irradiated onto the subject. For example, one candidate is a material that transmits light at the specific wavelength while at the same time having an absorption band, such as a color filter (e.g., R/G/B/cyan/magenta) that partially does not transmit wavelengths from the visible to near infrared range. Another candidate is the all-pass white filter W that passes wavelengths from the visible to infrared range at least including the specific wavelength. In the case of the fifth example, a filter of a considerable thickness (e.g., 1 μm) is required to pass only the specific wavelength. The compatibility with the thickness of the red, green and blue color filter (e.g., about 600 to 700 nm) becomes a problem. In contrast, there is basically no filter thickness problem with the sixth example. That is, the sixth example is a preferred mode to ensure compatibility in terms of height of the color filter structure.

The term “material that transmits light at the specific wavelength irradiated onto the subject” refers to a material that transmits both visible and infrared light and differs from the infrared filter IR (that does not transmit visible light) used in the fifth example. This material may be alternatively implemented by applying the same philosophy as for the red, green and blue color filter and selecting a material to be used as appropriate.

### Seventh Example

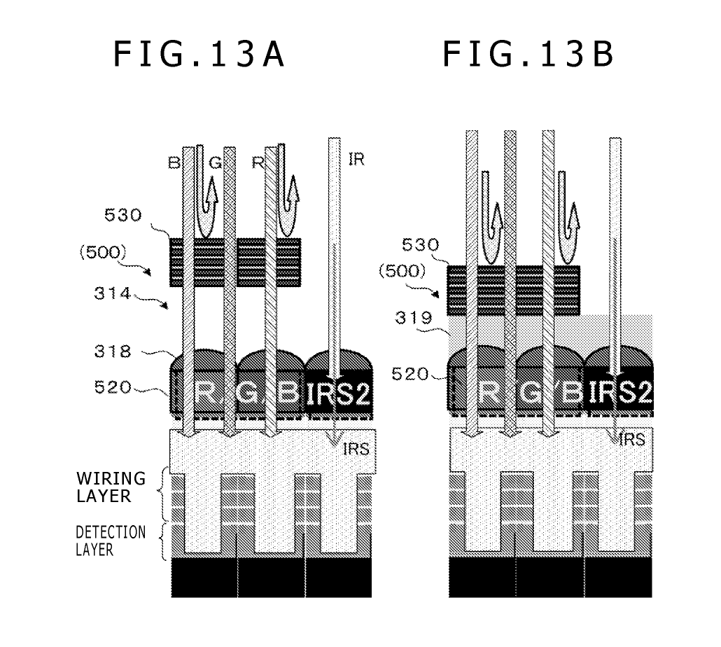

FIGS. 13A and 13B are diagrams illustrating a seventh example of a combination of a light source (light at a specific wavelength), optical filter section and imaging device structure.

The seventh example is a modification example of the fifth example. FIG. 13A illustrates an example of application to the configuration shown in FIG. 11A, and FIG. 13B an example of application to the configuration shown in FIG. 11B. In the seventh example, the optical band-pass filter 504 or 508 is replaced by an optical band-pass filter 530.

First of all, the color filter section 530 includes a band-pass filter adapted to remove the wavelengths other than visible light by absorption or reflection (so-called infrared cutoff filter) in the area for the visible pixels. Further, the color filter section 530 has no optical band-pass filter member in the area for the infrared light pixel (so that there is an opening). That is, in the seventh example, a band-pass filter is provided over the visible pixels to obtain a color image to remove the wavelengths other than visible light by absorption or reflection, and no band-pass filter is provided over the infrared light pixel to obtain distance information by detecting light at the specific wavelength irradiated onto the subject.

In this case, there is a concern that visible components and infrared components other than the specific wavelength may also be detected by the infrared light pixel. As a countermeasure, in the seventh example, the infrared filter IRS2 is provided in an on-chip manner together with the color filter group 312 (R/G/B) for color separation in the area for the infrared light pixel. The infrared filter IRS2 removes, by absorption or reflection, the wavelengths other than light at the specific wavelength irradiated onto the subject. The infrared filter IRS2 need only be implemented by combining two color filters, one high-pass and another low-pass, each of whose cutoff wavelength is set around the specific wavelength, as with the basic philosophy behind the manufacturing method of, for example, the special optical band-pass filter 502 which will be described later.

Although not illustrated, a deep area of the semiconductor layer may be used as an effective area for the infrared light pixel as illustrated in the sixth example. In this case, the infrared light pixel does not detect the visible components. Therefore, the infrared filter IRS2 may be replaced by an infrared filter IRS3 adapted to remove, by absorption or reflection, the wavelengths other than visible light and light at the specific wavelength irradiated onto the subject. The infrared filter IRS3 need only be implemented by combining two color filters, one high-pass and another low-pass, each of whose cutoff wavelength is set around the specific wavelength, as with the basic philosophy behind the manufacturing method of, for example, the special optical band-pass filter 502 which will be described later.

### Eighth Example

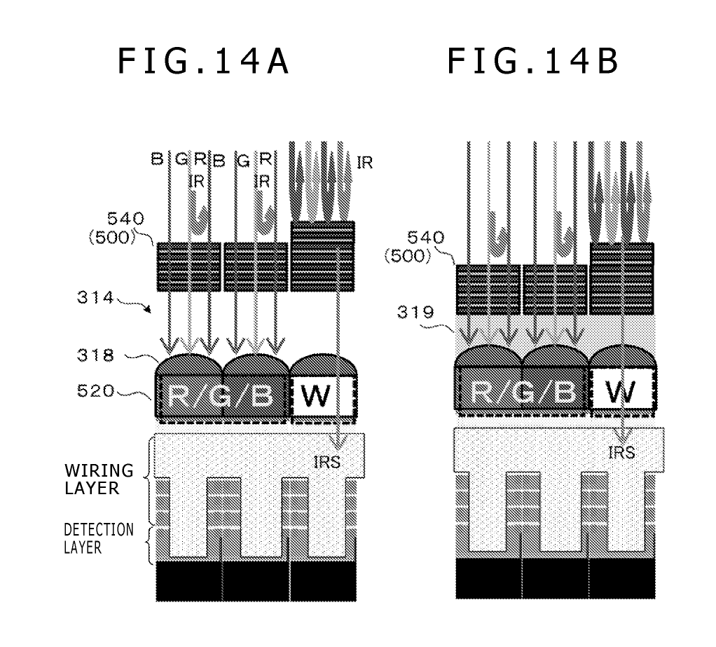

FIGS. 14A and 14B are diagrams illustrating an eighth example of a combination of a light source (light at a specific wavelength), optical filter section and imaging device structure.

The eighth example is a modification example of the fifth example. FIG. 14A illustrates an example of application to the configuration shown in FIG. 11A, and FIG. 14B an example of application to the configuration shown in FIG. 11B. In the eighth example, the optical band-pass filter 504 or 508 is replaced by an optical band-pass filter 540. When looked at from a different point of view, the eighth example is a modification example of the seventh example in which the optical band-pass filter 530 is replaced by the optical band-pass filter 540.

First of all, the optical band-pass filter 540 includes a band-pass filter (so-called infrared cutoff filter) adapted to remove the wavelengths other than visible light by absorption or reflection in the area for the visible pixels. Further, the optical band-pass filter 540 includes a special band-pass filter (made of the same member as for the optical band-pass filter 502) in the area for the infrared light pixel. This special band-pass filter transmits light at the specific wavelength irradiated onto the subject and removes all other wavelengths by absorption or reflection. That is, the opening of the optical band-pass filter 530 is replaced by that made of the same member as for the optical band-pass filter 502). In this case, unlike the seventh example, no color filter is required over the infrared light pixel to absorb or reflect special wavelengths.

It should be noted that if it is structurally difficult to manufacture the device (due, for example, to the arrangement of the on-chip microlenses) without a color filter provided over the infrared pixel to absorb or reflect special wavelengths, a material may be used instead that is easy to use in the manufacturing process and transmits at least light at the specific wavelength irradiated onto the subject. For example, one candidate is a material that transmits light at the specific wavelength while at the same time having an absorption band, such as a color filter (e.g., R/G/B/cyan/magenta) that does not partially transmit wavelengths from the visible to near infrared range. Another candidate is the all-pass white filter W that passes wavelengths from the visible to infrared range including at least the specific wavelength.

### <Details of the Special Optical Band-Pass Filter>

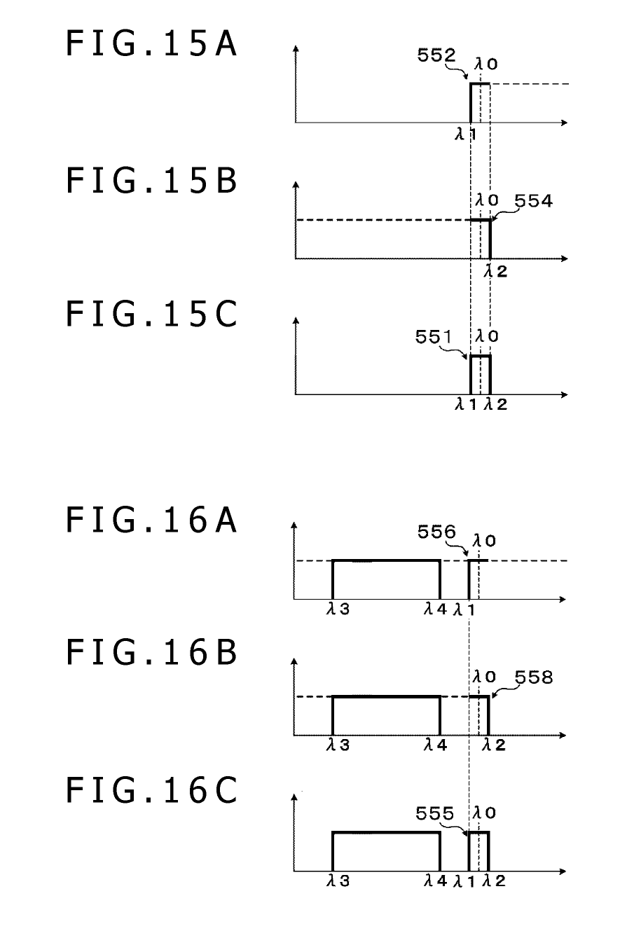

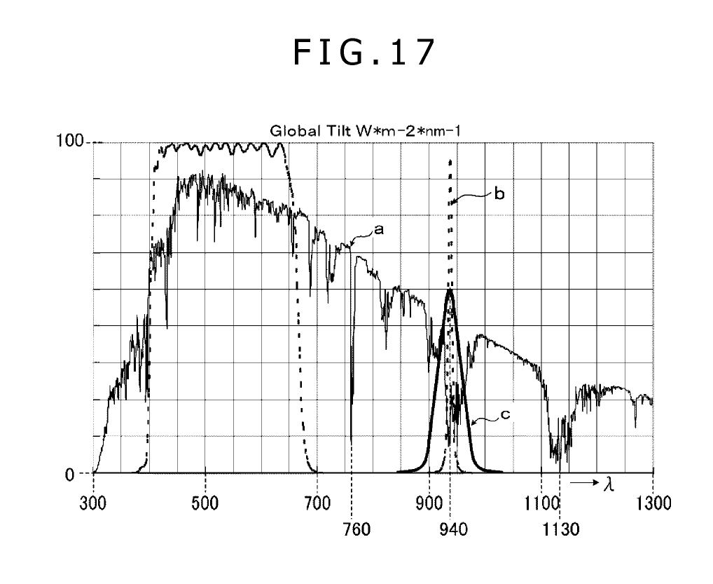

FIGS. 15A to 17 are diagrams describing the manufacturing method of an optical member (special optical band-pass filter, and the like) having a narrow band-pass characteristic centered around the specific wavelength. FIGS. 15A to 15C are diagrams illustrating the basic philosophy behind the manufacturing method of the optical member having a band-pass characteristic. FIG. 17 is a diagram describing a specific example of the optical member having a band-pass characteristic.

An optical member having a band-pass characteristic such as the optical band-pass filter 502 or 506 need be designed to transmit light at the specific wavelength but not light at wavelengths other than the specific wavelength. The optical band-pass filter 504 or 508 adapted to transmit the visible band need be designed to transmit visible light and light at the specific wavelength but not light at other wavelengths. In any case, the filter need have a narrow transmission band to transmit only a narrow band including the specific wavelength.

It is difficult to implement such an optical filter having a narrow transmission band for light at the specific wavelength with one type of optical filter. In the case of an ordinary so-called infrared cutoff filter including an absorbent material, for example, there is no absorbent material that shows a sharp change in transmission only in a given band of wavelengths of the infrared range. Further, even if a multi-layer film is used to block infrared light, it is difficult to design a multi-layer film that transmits only a narrow band of specific wavelengths in the infrared range.

As a countermeasure, an optical band-pass filter 551 is used as an optical member having a band-pass characteristic to transmit only light at the specific wavelength as illustrated in FIGS. 15A to 15C. The optical band-pass filter 551 includes a combination of a high-pass filter 552 having a cutoff wavelength around a specific wavelength λ0 and a low-pass filter 554 having a cutoff wavelength around the specific wavelength λ0.

As illustrated in FIG. 15A, the high-pass filter 552 has a cutoff wavelength at a wavelength λ1 that is slightly shorter than the specific wavelength λ0. For example, if the specific wavelength λ0 is 940 nm, one of the absorbed solar wavelengths, the high-pass filter 552 has a cutoff wavelength about 10 nm shorter than 940 nm (λ1=around 930 nm), transmitting the wavelengths longer than the cutoff wavelength. It should be noted that whether the high-pass filter 552 transmits the wavelengths longer than a wavelength λ2 to be cut off by the low-pass filter 554 does not matter.

As illustrated in FIG. 15B, the low-pass filter 554 has a cutoff wavelength at the wavelength λ2 that is slightly longer than the specific wavelength λ0. For example, if the specific wavelength λ0 is 940 nm, one of the absorbed solar wavelengths, the low-pass filter 554 has a cutoff wavelength about 10 nm longer than 940 nm (λ2=around 950 nm), transmitting the wavelengths shorter than the cutoff wavelength. It should be noted that whether the low-pass filter 554 transmits the wavelengths shorter than a wavelength λ1 to be cut off by the high-pass filter 552 does not matter.

If the optical band-pass filter 551, i.e., an optical member, includes a combination of the high-pass filter 552 and low-pass filter 554 as described above, the optical band-pass filter 551 has a band-pass characteristic with two cutoff wavelengths centered around the specific wavelength λ0, one at the wavelength λ1 on the side of shorter wavelengths and another at the wavelength λ2 on the side of longer wavelengths, as illustrated in FIG. 15C. For example, if the specific wavelength λ0 is 940 nm, one of the absorbed solar wavelengths, the optical band-pass filter 551 blocks the wavelengths shorter than around 930 nm, transmits those from around 930 nm to around 950 nm and blocks those longer than around 950 nm.

An optical band-pass filter 555 is used as an optical member having a band-pass characteristic to transmit visible light and light at the specific wavelength as illustrated in FIGS. 16A to 16C. The optical band-pass filter 555 includes a combination of a special high-pass filter 556 and special low-pass filter 554.

As illustrated in FIG. 16A, the high-pass filter 556 transmits the wavelengths in the visible band (wavelength λ3 to λ4) and has a cutoff wavelength at the wavelength λ1 that is slightly shorter than the specific wavelength λ0. For example, if the specific wavelength λ0 is 940 nm, one of the absorbed solar wavelengths, the high-pass filter 556 transmits the wavelengths from λ3 to λ4 and has a cutoff wavelength about 10 nm shorter than 940 nm (λ1=around 930 nm), transmitting the wavelengths longer than the cutoff wavelength. It should be noted that whether the high-pass filter 556 transmits the wavelengths longer than the wavelength λ2 to be cut off by the low-pass filter 558 does not matter.

As illustrated in FIG. 16B, the low-pass filter 558 transmits the wavelengths in the visible band (wavelength λ3 to λ4) and has a cutoff wavelength at the wavelength λ2 that is slightly longer than the specific wavelength λ0. For example, if the specific wavelength λ0 is 940 nm, one of the absorbed solar wavelengths, the low-pass filter 558 transmits the wavelengths from λ3 to λ4 and has a cutoff wavelength about 10 nm longer than 940 nm (λ2=around 950 nm), transmitting the wavelengths shorter than the cutoff wavelength. It should be noted that whether the low-pass filter 558 transmits the wavelengths shorter than the wavelength λ1 to be cut off by the high-pass filter 556 (excluding the wavelengths from λ3 to λ4 in the visible band) does not matter.

If the optical band-pass filter 555, i.e., an optical member, includes a combination of the high-pass filter 556 and low-pass filter 558 as described above, the optical band-pass filter 555 has a band-pass characteristic with two cutoff wavelengths centered around the specific wavelength λ0, one at the wavelength λ1 on the side of shorter wavelengths and another at the wavelength λ2 on the side of longer wavelengths, as illustrated in FIG. 16C. In addition, the optical band-pass filter 555 transmits the wavelengths from λ3 to λ4 in the visible band. It should be noted that, as for the wavelengths from λ3 to λ4 in the visible band, the cutoff wavelength λ3 on the side of shorter wavelengths and the cutoff wavelength λ4 on the side of longer wavelengths need be determined according to the combination of the high-pass filter 556 and low-pass filter 558 as with the concept regarding the specific wavelength within the range from λ1 to λ2 shown in FIGS. 15A to 15C. Which filter (filter 556 or 558) has a low-pass characteristic for visible light and which other a high-pass characteristic for visible light can be determined freely. For example, even if the specific wavelength λ0 is 940 nm, one of the absorbed solar wavelengths, the optical band-pass filter 555 blocks the wavelengths shorter than around 930 nm (excluding the wavelengths from λ3 to λ4 in the visible band), transmits those from around 930 nm to around 950 nm and blocks those longer than around 950 nm.

It is only necessary to use a filter made, for example, of a multi-layer film as each of the high-pass filter 552, low-pass filter 554, high-pass filter 556 and low-pass filter 558. These filters should be structured based on the concept of wavelength separation adapted to separate electromagnetic wave into given wavelengths making use of dielectric stacks. That is, these filters should each include a plurality of layers stacked one on top of another, with the adjacent layers having different refractive indices and given thickness, thus taking advantage of dielectric stacks serving as a laminated member adapted to reflect the wavelength components (light at the specific wavelength and visible light in the present example) other than target components in incident light (electromagnetic wave) and transmit the rest (light at the specific wavelength and visible light in the present example).

These optical band-pass filters 551 and 555 have not found application in existing distance measurement sensors using infrared light because of lack of need for precise identification of wavelengths. Similarly, these filters have not found application in visible camera systems. On the other hand, it is practically difficult to obtain a desired special band-pass characteristic that shows an extremely sharp change in transmission using a single type of optical filter. In contrast, high-pass and low-pass characteristics are combined in the second embodiment as described above. As a result, it is possible to obtain, with relative ease, a desired special band-pass characteristic, i.e., a narrow band-pass characteristic (with a sharp change in transmission) centered around the specific wavelength λ0.

FIG. 17 illustrates a specific example of the optical band-pass filter 555, an example of an optical member having a band-pass characteristic. This figure shows the relationship in spectral characteristic between solar light reaching the ground, the specific band-pass filter and the light source adapted to irradiate light onto the subject. For purposes of description, a relative scale is given along the vertical axis for the three spectral characteristic graphs.

An arrow ‘a’ in FIG. 17 shows the characteristic of solar wavelengths reaching the ground. An arrow ‘b’ shows the transmissivity/wavelength characteristic of the optical band-pass filter 555. An arrow ‘c’ around 940 nm, i.e., absorbed solar wavelength and specific wavelength, shows the wavelength characteristic of the light source (e.g., LED (Light Emitting Diode)) adapted to irradiate light onto the subject. In the example shown in FIG. 17, only light in the visible band and light around 940 nm can pass through the optical band-pass filter 555, resulting in an extremely small amount of infrared light reaching the pixels. Further, when the subject is irradiated with light from the LED light source having a peak wavelength at 940 nm, light around 940 nm can pass through the optical band-pass filter 555. As a result, as far as light around 940 nm is concerned, light irradiated onto the subject from the light source accounts for a large percentage in comparison with solar light. It should be noted that the characteristics shown in FIG. 17 are merely an example. The transmission bandwidth of the optical band-pass filter 555 and the bandwidth of the LED light source are not limited thereto.

### Examples of Problems

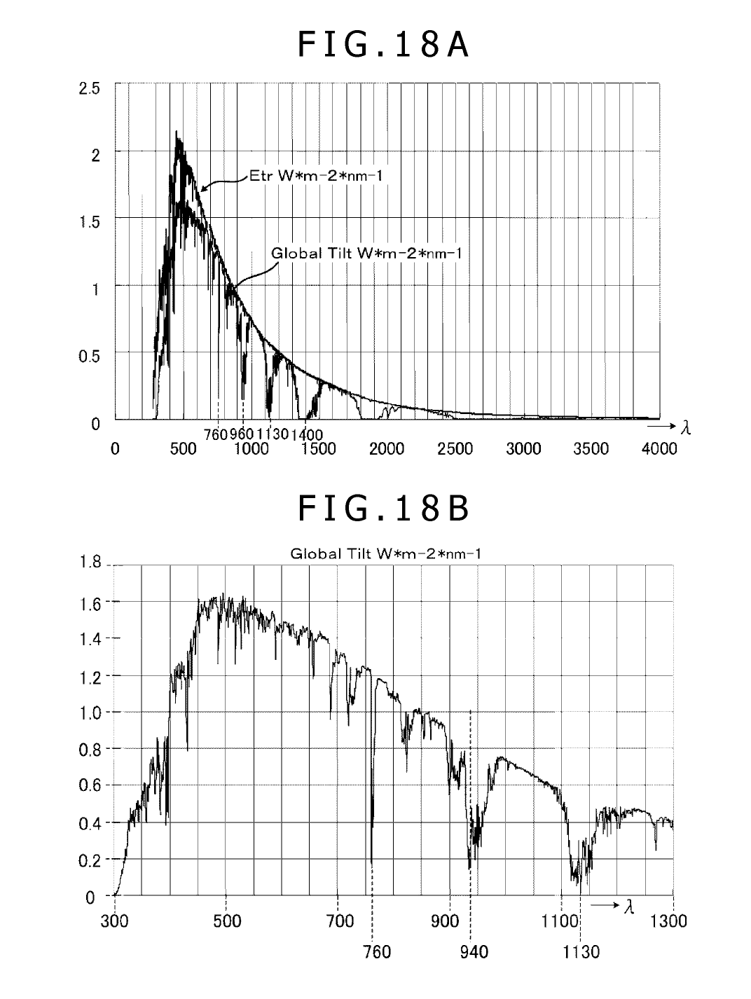

FIGS. 18A and 18B are diagrams describing wavelength components of solar light reaching the ground (electromagnetic wave energy level). It is clear from the data publicly disclosed in Reference Solar Spectral Irradiance: ASTM G-173 by National Renewable Energy Laboratory, US, that there are a plurality of bands of absorbed wavelengths in the solar wavelengths reaching the ground. More specifically, the absorption level is high around 760 nm, 940 nm, 1130 nm and 1400 nm.

It is only necessary to focus on the absorbed wavelength bands around 760 nm, 940 nm and 1130 nm as far as the wavelength bands up to around 1100 nm are concerned where ordinary silicon has photoelectric conversion sensitivity. If silicon called black silicon is used as a basic material for enhanced sensitivity and expansion of sensitivity up to the infrared band, the wavelength where the material no longer has photoelectric conversion sensitivity can be expanded beyond 1400 nm. In this case, attention should also be focused on the absorbed wavelength band around 1400 nm.

Here, solar light components as shown in FIGS. 18A and 18B are detected outdoors at daytime. As is clear from FIGS. 18A and 18B, solar light is extremely intense in the visible band. Solar light is also very intense in the infrared band, although not as intense as in the visible band. Considering a distance measurement camera system, the distance to the subject is measured by irradiating infrared light onto the subject from the infrared light source for distance measurement and receiving reflected light. However, solar light is intense even in the infrared band. Even if, for example, an ordinary 850 nm LED light source is used that incorporates a visible cutoff filter, the sum of intensity of solar light from 750 nm to 1100 (or 1400) nm constitutes a noise component. This noise component is considerably more intense than the LED light, a signal component, making the distance measurement difficult outdoors at daytime.

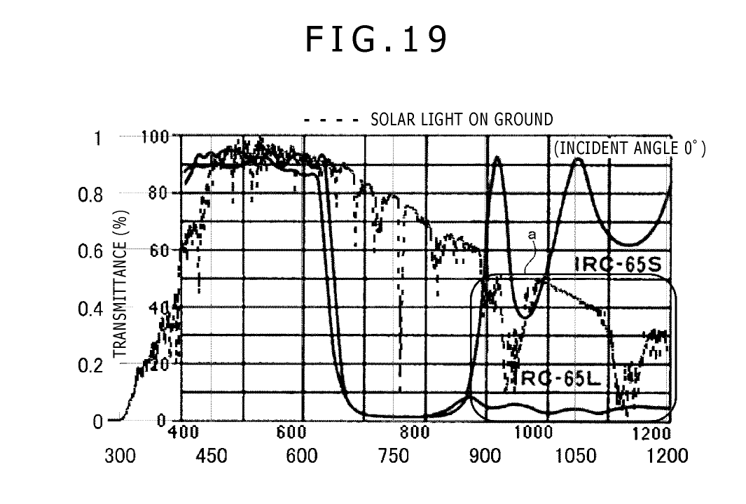

FIG. 19 is a diagram illustrating characteristic examples of infrared cutoff filters. FIG. 19 shows the filter characteristics superposed with the characteristic of the absorbed solar wavelengths on the ground. The infrared cutoff filters shown in FIG. 19 are IRC-65S and IRC-65L from Kenko Co., Ltd. Both of these filters transmit visible light and cut off near infrared light around 700 to 800 nm, with their 50% cutoff wavelength set around 650 nm. As is clear from this figure, however, a sub-transmission band occurs beyond 850 nm in the case of the IRC-65S. As a result, the IRC-65S has a certain extent of transmissivity in this sub-transmission band.

Therefore, solar light beyond 850 nm that may not be cut off by the infrared cutoff filter (e.g., IRC-65S) having a sub-transmission band is converted into an electric signal by the image sensor, thus resulting in a noise component. In the case of the IRC-65S (assuming that the filter transmits almost all wavelengths beyond 900 nm for simplicity), for example, a sum P of solar light energy (900 nm to 1200 nm: border line ‘a’ in FIG. 19) is 153 [W/m̂2]. Using any part of the wavelengths beyond 850 nm excluding the absorbed solar wavelengths in this condition will lead to difficulty in providing basically improved S/N ratio due to a large amount of noise component.

For example, the distance to an object is detected by irradiating near infrared light onto the object and receiving reflected light from the object. For example, a wavelength beyond 850 nm is primarily used as near infrared light. Among active measurement methods are the triangular surveying and TOF (time of flight) methods. All these methods obtain distance information by irradiating near infrared light onto the subject.

Here, disturbance noise caused by solar light is a serious problem when distance measurement is conducted outdoors. There are some possible countermeasures. One possible countermeasure would be to irradiate light from a powerful infrared light source for increasing signal components. Another possible countermeasure would be to have ready two pixels, one for “reflected infrared light from the object and external light” and another for “external light” and take the difference between the two.

However, because of the presence of fundamental disturbance noise caused by powerful solar light as intense as 100000 lux, it is fundamentally difficult to enhance the S/N ratio. Further, intense solar light results in sensor saturation.

### Examples of the Second Embodiment

On the other hand, the solar wavelengths around 760 nm, 940 nm, 1130 nm and 1400 nm reaching the ground are absorbed outdoors by the atmosphere. Therefore, matching the wavelength of the light source to one of these wavelengths makes it possible to avoid noise components in the infrared band caused by solar light outdoors. If the optical band-pass filter 506 is provided to transmit reflected light from the subject after irradiating light at one of the above wavelengths onto the subject from the light-emitting section 322, it is possible to provide significantly improved S/N ratio (Signal-Noise ratio) which would otherwise be degraded by direct disturbance.

In this regard, the second embodiment is identical to the first embodiment. However, matching the wavelength of the light source to one of the specific wavelengths alone results in the remaining infrared components being detected. As a result, a comparison process such as a difference-taking process is almost absolutely essential to obtain correct information derived from the specific wavelength. Besides, the saturation problem remains to be solved.

The second embodiment focuses on this feature. In addition to the arrangement according to the first embodiment adapted to match the wavelength of the light source to one of the specific wavelengths in the infrared range, an optical member having a band-pass characteristic centered around the specific wavelength is provided in the imaging optical path to allow for the infrared pixel to detect only the specific wavelength in the second embodiment.

Providing the optical band-pass filter 506 as an example of an optical element, i.e., an infrared cutoff filter adapted to cut off noise components in the infrared range and transmit the components in the specific wavelength band of the light source, makes it possible to avoid detection of the components other than the specific wavelength by the detection section. The reduction in undesired incident solar light components other than light at the specific wavelength solves the saturation problem.

The solid-state imaging element 314 or imaging system configured as described above provides a signal with minimal disturbance noise outdoors and avoids the problem of photoreception element saturation due to reduction in undesired incident solar light. This allows for highly accurate distance measurement and object detection not only indoors but also under the sun.

If an optical member having a band-pass characteristic centered around the specific wavelength is integral with the solid-state imaging device (particularly, solid-state imaging element), it is possible for a single solid-state imaging element to obtain a monochrome or color image and infrared information at the same time.

Simultaneous acquisition of a monochrome or color image and a measurement image derived from light at the specific wavelength from the light source adapted to irradiate light onto the subject allows, for example, for distance measurement outdoors at daytime using a signal based on light at the specific wavelength irradiated onto the subject.

It should be noted that any active measurement method such as the triangular surveying or TOF (time of flight) method may be used in the present embodiment. On the other hand, any method may be used to drive the light source, configure the light source and photoreception optical system and process the acquired optical signal.

For example, if the TOF method is used with the specific wavelength set at 940 m, an 940 nm LED light source is, for example, used, and four types of pixels, red, green, blue and infrared, are provided on the solid-state imaging element 314. The light source is modulated at high speed. Each of the red, green and blue pixels of the solid-state imaging element 314 outputs an electric signal converted from light using the same driving method as for ordinary shooting. The infrared pixel obtains a measurement image based on light at the specific wavelength modulated by the light source. As for the distance measurement calculation adapted to derive the distance from the time it takes for light at the specific wavelength emitted from the light source to return to the solid-state imaging element 314, it is only necessary to use the method described, for example, in Patent Document 4.

### Comparison with Comparative Examples

### First Comparative Example

The arrangement described in Patent Document 3 is used as a first comparative example. In the first comparative example, auxiliary light is irradiated, and reflected light is received by the “red, blue and green pixels and invisible pixel.” The distance measurement relies on a physical phenomenon that the luminance of reflected light from an object is inversely proportional to the square of the distance. As described in the first comparative example, the reflectance varies from one substance to another. Therefore, the difference in reflectance between the substances is corrected. Further, in the first comparative example, a natural light image and target material (reflection characteristic) information, for example, are referenced at the same time to estimate the reflection factor from the color information of the target surface. In reality, however, it is difficult to identify the object only from the color information of the target surface. In order to identify the object, image recognition is required using signal processing that relies not only on the color information of the target surface but also on the shape and color, etc.

Further, even if the object is successfully identified, it is difficult to identify the reflectance because the surface condition of a natural object such as a human or animal body varies from one individual to another. This process is difficult to achieve in real time. For example, it is difficult to continue to obtain depth information at a frame rate of 10 to 30 frames a second. Even if the process can be achieved in real time, it is difficult to identify the reflectance of the object as described earlier, which makes this process difficult to achieve.

### Second Comparative Example

The arrangement described in Patent Document 2 to which the triangular surveying is applied is used as a second comparative example. In the second comparative example, the distance to the target is calculated by repeatedly projecting a pulsed luminous flux and using a photoreception section and signal current accumulation section. The photoreception section receives reflected light from the target. The signal current accumulation section accumulates the signal current obtained by the photoreception section. The signal accumulated by the signal current accumulation section is used to calculate the distance to the target. An accumulation time change section is provided to change the maximum effective time to accumulate the signal current depending on the target condition. Further, the target brightness is determined so that the maximum effective signal accumulation time is changed according to the determination result. More specifically, if the brightness is at a level that may cause decline in S/N ratio due to shot noise (if the brightness is determined to be higher than the predetermined level), the maximum effective signal accumulation time is set long so that a weak signal can be accumulated over a longer signal accumulation time for improved S/N ratio. In a dark condition where the impact of shot noise is negligible, on the other hand, the maximum effective signal accumulation time is set short to shorten the distance measurement time.

The second comparative example focuses on the shot noise characteristic in relation to the deterioration of the S/N ratio caused by shot noise N2. That is, the signal component becomes larger proportionally to the signal accumulation time. However, the shot noise component is proportional to the square root of the signal accumulation time. Therefore, extending the signal accumulation time gradually improves the S/N ratio almost proportionally to the square root of the signal accumulation time, thus providing improved S/N ratio. Normally, however, disturbance light is present in the shooting environment that has a component at the same wavelength as the signal light. As a result, the signal light here is made up of “signal light and disturbance light N3.” The S/N ratio including the disturbance light component N3 can be expressed by the relationship S/(√(N1̂2+N2̂2)+N3) where N1 is the level of circuit noise.

On the other hand, a wide variety of light from visible to infrared light is present outdoors. Therefore, a proportional relationship holds for the S/N ratio between the signal light and disturbance light even if the signal is accumulated for extended periods. This leads to failure to achieve an anticipated improvement effect. It is difficult to provide improved S/N ratio by controlling the exposure time. Outdoor disturbance light is extraordinarily more intense than the signal light. In order to counter disturbance light, there is no alternative but to intensify the signal light. As a result, a significantly powerful light source is required, thus resulting in upsizing or higher power consumption.

### Third Comparative Example

The arrangement described in Patent Document 4 to which the TOF method is applied is used as a third comparative example. In the third comparative example, a near infrared emitting LED having a peak wavelength, for example, at 870 nm is used in contrast to solar light having a peak wavelength in the visible band (about 500 nm). Additionally, light in the visible band is removed by an appropriate visible cutoff filter. This makes it possible to use infrared light that is weaker in intensity than the most intense light (visible components) contained in solar light, thus providing reduced noise component.

Here, if filters adapted to remove invisible light are provided on the visible pixels, and a filter adapted to remove visible light is provided on the invisible pixel (configuration shown in FIG. 12) in the third comparative example, the outdoor solar light is extremely intense. Therefore, the sum of intensity of the received infrared components excluding infrared light even with 870 nm infrared light used as auxiliary light remains incomparably larger than auxiliary light. Even the technique shown in the third comparative example fails to reduce the fundamental solar light components that constitute a noise component. Therefore, it is difficult to obtain a reflected component (signal light) of auxiliary light sufficient in intensity for measurement. If auxiliary light sufficiently intense as compared to solar light is used, it is possible to obtain signal light. Instead, upsizing or higher power consumption is inevitable because an extremely large output is required of the auxiliary light source. This leads to upsizing or shorter usage time of the camera system, thus making this comparative example difficult to achieve.

### Fourth Comparative Example

The arrangement using an irradiation pattern and described in Patent Document 1 is used as a fourth comparative example. In the fourth comparative example, an optical three-dimensional shape measurement device is disclosed. This device includes an irradiation optical system and observation optical system. The irradiation optical system projects a given pattern image onto the target surface. The observation optical system is used to observe the pattern image projected onto the target surface. The target surface shape is measured based on the change in observed pattern image. The irradiation optical system includes a focusing surface division section adapted to form a given pattern image on each of a plurality of focusing surfaces along the optical axis.

In the fourth comparative example, however, it is necessary to irradiate a pattern onto the plurality of focusing surfaces at different timings and perform image recognition so as to obtain the deformation of the irradiation pattern by image recognition and obtain depth information based on the deformation thereof. If the number of pixels is large, extremely extensive calculations are required, thus making real time measurement difficult. If a given pattern is formed on the plurality of focusing surfaces at the same time to avoid the above problem, it is impossible to separate the patterns on the different focusing surfaces, thus making the pattern recognition difficult.

### [Comparison]

In any of the first to fourth comparative examples, disturbance noise caused by solar light is a serious problem when the arrangements are used outdoors. Although light in the infrared range is used as a light source because infrared components of solar light are less intense than its visible components, it is extremely difficult to detect a signal of sufficient level considering the constituents and energy levels of solar light reaching the ground.

For example, even if an 870 nm LED light source is used as described in the third comparative example, there are many noise components of solar light other than 870 nm. As a result, it is difficult to fundamentally improve the S/N ratio. In the case of cancellation of a noise component of solar light by taking the difference between the two pixels, difference calculation for the noise component of solar light that has already been converted into an electric signal leads to noise as a result of the signal level during photoelectric conversion as in the second comparative example. As a result, difference calculation cannot fundamentally cancel the entire noise component. The photoreception element becomes saturated due to intense solar light. A special circuit may be added to deal with the saturation problem (e.g., Japanese Patent Laid-Open No. 2008-089346). However, this results in a larger circuit scale.

In the second embodiment, on the other hand, a light source is used that emits light at a specific wavelength equivalent to that of one of the absorbed solar wavelengths. Further, an optical member is provided in the imaging optical path that has a narrow band-pass characteristic centered around the specific wavelength. This prevents reception of components other than the specific wavelength. As described above, the second embodiment makes it possible to avoid not only the noise problem caused by components other than the specific wavelength but also the saturation problem without using any special circuit.

Although the preferred embodiments of the present invention have been described above, the technical scope of the present invention is not limited to those described in the embodiments. The present invention may be modified or improved in various ways without departing from the spirit of the invention, and such a modified or improved mode of implementation is included in the technical scope.

Further, it should be understood that the preferred embodiments do not restrict the invention, and all the combinations of the features described in the embodiments are not necessarily essential to the sections for solving the problems of the invention. The above embodiments include various stages of the present invention, and various inventions can be extracted by appropriately combining a plurality of disclosed constituent requirements. Even if some constituent requirements are deleted from all the constituent requirements disclosed in the embodiments, the configuration devoid of several constituent requirements may be extracted as an invention so long as the intended effect can be achieved.

For example, although a description has been given of the embodiments with primary focus on the specific wavelengths in the infrared range (particularly, absorbed solar wavelengths), the specific wavelengths are not limited to those in the infrared range as described at the beginning of the first example of the second embodiment. Further, although a description has been given of examples of acquisition of distance information and a three-dimensional image as examples of acquisition of physical information, the acquisition of physical information using a specific wavelength is not limited thereto.

The present application contains subject matter related to that disclosed in Japanese Priority Patent Application JP 2010-067231 filed in the Japan Patent Office on Mar. 24, 2010, the entire content of which is hereby incorporated by reference.

What is claimed is:

1. A physical information acquisition device comprising:
an electromagnetic wave output section adapted to generate electromagnetic wave at a wavelength equivalent to a specific wavelength when, for a first wavelength range of electromagnetic wave, a wavelength where electromagnetic wave energy is lower than at other wavelengths is determined to be the specific wavelength;
a first detection section adapted to detect electromagnetic wave at the specific wavelength; and
a signal processing section adapted to perform signal processing based on detection information acquired from the first detection section.

2. The physical information acquisition device according to claim 1, wherein
a second wavelength range is the visible wavelength range, and the first wavelength range is the wavelength range excluding the first wavelength range.

3. The physical information acquisition device according to claim 2, wherein
the first wavelength range is the infrared range.

4. The physical information acquisition device according to claim 3, wherein
the specific wavelength is one of absorbed wavelengths of solar light reaching the ground.

5. The physical information acquisition device according to claim 1, wherein
the first wavelength range is the visible wavelength range, and the specific wavelength is in a range of wavelengths different from the wavelength of a light source adapted to emit a spectrum at a specific wavelength in the visible band.

6. A physical information acquisition device comprising:
an electromagnetic wave irradiation section adapted to irradiate irradiation light onto an object whose image is to be acquired;
a first detection section adapted to detect electric charge of an image component when the object is illuminated with irradiation light irradiated from the electromagnetic wave irradiation section;
a second detection section adapted to detect electric charge of the image component when the object is illuminated with natural light; and
a signal processing section adapted to perform signal processing based on detection information acquired from the first and second detection sections, wherein
the electromagnetic wave irradiation section generates light at some specific wavelengths in the wavelength range other than the range of visible wavelengths.

7. The physical information acquisition device according to claim 1, wherein
a first optical member having a band-pass characteristic centered around the specific wavelength is provided in the imaging optical path.

8. The physical information acquisition device according to claim 7, wherein
the first optical member removes the wavelengths other than the specific wavelength.

9. The physical information acquisition device according to claim 7, wherein
the first optical member suppresses the wavelength components other than visible light and the specific wavelength.

10. The physical information acquisition device according to claim 7, wherein
the first optical member includes a combination of a high-pass filter having a cutoff wavelength slightly shorter than the specific wavelength and a low-pass filter having a cutoff wavelength slightly longer than the specific wavelength.

11. The physical information acquisition device according to claim 1 comprising:
a second detection section adapted to detect electromagnetic wave in the second wavelength range that does not include the first wavelength range.

12. The physical information acquisition device according to claim 9 comprising:
the second detection section adapted to detect electromagnetic wave in the second wavelength range that does not include the first wavelength range, wherein
the first detection section detects the components in the first wavelength range longer in wavelength than those in the second wavelength range, wherein
the first and second detection sections are disposed in a predetermined order on the same semiconductor substrate, and wherein
the effective detection area of the first detection section is provided at a deeper position from the surface of the semiconductor substrate than that of the second detection section.

13. The physical information acquisition device according to claim 12, wherein
the effective area where a first conductivity type dopant of the first detection section is formed extends deeper from the surface of the semiconductor substrate than that where the first conductivity type dopant of the second detection section is formed.

14. The physical information acquisition device according to claim 13, wherein
modulation doping is performed in the effective area where the first conductivity type dopant of the first detection section is formed so that the deeper the location from the surface of the semiconductor substrate, the lower the doping concentration.

15. The physical information acquisition device according to claim 9, wherein
a second optical member is provided in the photoreception optical path of the first detection section to suppress electromagnetic wave in the second wavelength range that does not include the first wavelength range.

16. The physical information acquisition device according to claim 6, wherein
a color filter is provided in the area along the optical path for the second detection section to separate the visible band into different colors.

17. The physical information acquisition device according to claim 16, wherein
a color filter is provided in the area along the optical path for the first detection section to suppress visible light.

18. The physical information acquisition device according to claim 1, wherein
the signal processing section measures the distance to the subject or detects an object based on image information derived from the specific wavelength component.

19. A solid-state imaging device comprising:
a detection section adapted to detect a component emitted from an electromagnetic wave output section adapted to generate electromagnetic wave at a wavelength equivalent to a specific wavelength when, for a first wavelength range of electromagnetic wave, a wavelength where electromagnetic wave energy is lower than at other wavelengths is determined to be the specific wavelength, the component reflected by an object, wherein
an optical member having a band-pass characteristic centered around the specific wavelength is provided in the imaging optical path.

20. A physical information acquisition method comprising the steps of:
irradiating an object with electromagnetic wave at a wavelength equivalent to a specific wavelength when, for a first wavelength range of electromagnetic wave, a wavelength where electromagnetic wave energy is lower than at other wavelengths is determined to be the specific wavelength;
detecting electromagnetic wave at the specific wavelength reflected by the object with a detection section; and
performing signal processing based on detection information acquired from the detection section.
